(19) United States
(12) Patent Application Publication
(10) Pub. No.: US 2015/0034151 A1
(43) Pub. Date: Feb. 5, 2015

(54) INVERTED METAMORPHIC MULTIJUNCTION SOLAR CELL WITH PASSIVATION IN THE WINDOW LAYER

(71) Applicant: Emcore Solar Power, Inc., Albuquerque, NM (US)

(72) Inventor: Arthur Cornfeld, Sandia Park, NM (US)

(73) Assignee: Emcore Solar Power, Inc., Albuquerque, NM (US)

(21) Appl. No.: 13/954,610

(22) Filed: Jul. 30, 2013

(51) Int. Cl. H01L 31/0725; H01L 31/18; H01L 31/048; H01L 31/0216

(52) U.S. Cl. CPC H01L 31/0725; H01L 31/02167; H01L 31/1848; H01L 31/0481; H01L 31/02168
USPC 136/255; 438/66

(57) ABSTRACT

An inverted metamorphic multijunction solar cell including a window layer with sulfur passivation on the surface of the window layer of the top solar subcell.

### REFERENCE TO RELATED APPLICATIONS

This application is related to co-pending U.S. patent application Ser. No. ______ filed simultaneously herewith.

This application is related to co-pending U.S. patent application Ser. No. 13/921,756 filed Jun. 19, 2013.

This application is related to co-pending U.S. patent application Ser. No. 13/836,742 filed Mar. 15, 2013.

This application is related to co-pending U.S. patent application Ser. No. 13/831,406 filed Mar. 14, 2013.

This application is related to co-pending U.S. patent application Ser. No. 13/768,683 filed Feb. 13, 2013.

This application is a related to U.S. patent application Ser. No. 12/637,241, filed Dec. 14, 2009, which is a continuation-in-part of U.S. patent application Ser. No. 11/616,596, filed Dec. 27, 2006, and Ser. No. 12/544,001, filed Aug. 19, 2009.

This application is related to co-pending U.S. patent application Ser. No. 13/604,833 filed Sep. 6, 2012, which is a continuation-in-part of U.S. patent application Ser. No. 12/637,241, filed Dec. 14, 2009, which in turn is a continuation-in-part of U.S. patent application Ser. No. 11/616,596, filed Dec. 27, 2006, and Ser. No. 12/544,001, filed Aug. 19, 2009.

This application is related to co-pending U.S. patent application Ser. No. 13/569,794 filed Aug. 9, 2012.

This application is related to co-pending U.S. patent application Ser. No. 13/547,334 filed Jul. 12, 2012.

This application is related to co-pending U.S. patent application Ser. No. 13/473,802 filed May 17, 2012.

This application is related to co-pending U.S. patent application Ser. No. 13/465,477 filed May 7, 2012.

This application is related to co-pending U.S. patent application Ser. No. 13/463,069 filed May 3, 2012.

This application is related to co-pending U.S. patent application Ser. No. 13/440,331 filed Apr. 5, 2012.

This application is related to co-pending U.S. patent application Ser. No. 13/415,425 filed Mar. 8, 2012.

This application is related to co-pending U.S. patent application Ser. No. 13/401,181 filed Feb. 21, 2012.

This application is related to co-pending U.S. patent application Ser. No. 13/372,068 filed Feb. 13, 2012.

This application is related to co-pending U.S. patent application Ser. No. 13/315,877 filed Dec. 9, 2011.

This application is related to co-pending U.S. patent application Ser. No. 12/844,673 filed Jul. 27, 2010.

This application is related to co-pending U.S. patent application Ser. No. 12/813,408 filed Jun. 10, 2010.

This application is related to U.S. patent application Ser. No. 12/775,946 filed May 7, 2010, now U.S. Pat. No. 8,187,907.

This application is related to co-pending U.S. patent application Ser. No. 12/716,814, filed Mar. 3, 2010.

This application is related to co-pending U.S. patent application Ser. No. 12/708,361, filed Feb. 18, 2010.

This application is related to co-pending U.S. patent application Ser. No. 12/544,001, filed Aug. 19, 2009.

This application is related to U.S. patent application Ser. No. 12/537,361, filed Aug. 7, 2009, now U.S. Pat. No. 8,262,856.

This application is related to co-pending U.S. patent application Ser. No. 12/337,014 filed Dec. 17, 2008, now U.S. Pat. No. 7,785,989.

This application is related to U.S. patent application Ser. No. 12/267,812 filed Nov. 10, 2008, now U.S. Pat. No. 8,236,600.

This application is related to co-pending U.S. patent application Ser. No. 12/190,449, filed Aug. 12, 2008, now U.S. Pat. No. 7,741,146, and its divisional patent application Ser. No. 12/816,205, filed Jun. 15, 2010, now U.S. Pat. No. 8,039,291.

This application is related to U.S. patent application Ser. No. 12/187,477, filed Aug. 7, 2008, now U.S. Pat. No. 8,263,853, and its co-pending divisional application U.S. patent application Ser. No. 13/560,663 filed Jul. 27, 2012.

This application is related to co-pending U.S. patent application Ser. No. 12/218,558 filed Jul. 16, 2008.

This application is related to co-pending U.S. patent application Ser. No. 12/123,864 filed May 20, 2008.

This application is related to co-pending U.S. patent application Ser. No. 12/023,772, filed Jan. 31, 2008.

This application is related to U.S. patent application Ser. No. 11/956,069, filed Dec. 13, 2007, and its divisional application Ser. No. 12/187,454 filed Aug. 7, 2008, now U.S. Pat. No. 7,727,795.

This application is also related to co-pending U.S. patent application Ser. No. 11/860,142 and Ser. No. 11/860,183 filed Sep. 24, 2007.

This application is also related to co-pending U.S. patent application Ser. No. 11/445,793 filed Jun. 2, 2006, and its divisional Ser. No. 12/758,390 filed Apr. 12, 2010.

### GOVERNMENT RIGHTS STATEMENT

This invention was made with government support under Contracts No. FA 9453-04-2-0041 awarded by the U.S. Air Force. The Government has certain rights in the invention.

### BACKGROUND OF THE INVENTION

1. Field of the Invention

The present invention relates to the field of semiconductor devices, and to fabrication processes and devices such as multijunction solar cells based on III-V semiconductor compounds including a metamorphic layer. Such devices are also known as inverted metamorphic multijunction solar cells.

2. Description of the Related Art

Solar power from photovoltaic cells, also called solar cells, has been predominantly provided by silicon semiconductor technology. In the past several years, however, high-volume manufacturing of III-V compound semiconductor multijunction solar cells for space applications has accelerated the development of such technology not only for use in space but also for terrestrial solar power applications. Compared to silicon, III-V compound semiconductor multijunction devices have greater energy conversion efficiencies and generally more radiation resistance, although they tend to be more complex to manufacture. Typical commercial III-V compound semiconductor multijunction solar cells have energy efficiencies that exceed 27% under one sun, air mass 0 (AM0), illumination, whereas even the most efficient silicon technologies generally reach only about 18% efficiency under comparable conditions. Under high solar concentration (e.g., 500×), commercially available III-V compound semiconductor multijunction solar cells in terrestrial applications (at AM1.5D) have energy efficiencies that exceed 37%. The higher conversion efficiency of III-V compound semiconductor solar cells compared to silicon solar cells is in part based on the ability to achieve spectral splitting of the incident radiation as the light passes through a stack or plurality of photovoltaic regions with different band gap energies, and accumulating the current from each of the regions.

Typical III-V compound semiconductor solar cells are fabricated on a semiconductor wafer in a stack or vertical, multijunction structures. The individual solar cells or wafers are then disposed in horizontal arrays, with the individual solar cells connected together in an electrical series circuit. The shape and structure of an array, as well as the number of cells it contains, are determined in part by the desired output voltage and current.

Inverted metamorphic solar cell structures based on III-V compound semiconductor layers, such as described in M. W. Wanlass et al., Lattice Mismatched Approaches for High Performance, III-V Photovoltaic Energy Converters (Conference Proceedings of the 31^{st} IEEE Photovoltaic Specialists Conference, Jan. 3-7, 2005, IEEE Press, 2005), present an important conceptual starting point for the development of future commercial high efficiency solar cells. However, the materials and structures for a number of different layers of the cell proposed and described in such reference present a number of practical difficulties relating to the appropriate choice of materials and fabrication steps.

In a stacked semiconductor structure, the “window” layer typically designates a semiconductor layer with a thickness of between 200 and 300 Angstroms that is disposed between the surface layer (which may be the antireflection coating or ARC layer, or the contact layer where there are grid lines over the top surface) and the emitter layer of a the top subcell, or between the tunnel diode and the emitter layer of a lower subcell. The window layer is a layer with a distinct composition from its adjoining layers and is introduced to improve subcell efficiency by preventing minority carrier recombination at the top surface of the emitter layer, thereby permitting the minority carriers present in the emitter to migrate to the pn junction of the subcell, thereby contributing to the extracted electrical current. By being identified as a distinct layer, the window layer will have a composition that differs from both the adjacent layer and the emitter layer, but will generally be lattice matched to both semiconductor layers. In some embodiments, the window layer could be pseudomorphic.

In some embodiments, the window layer may have a higher band gap than the adjacent emitter layer, with the higher band gap tending to suppress minority-carrier injection into the window layer, and as a result tending to reduce the recombination of electron-hole pairs that would otherwise occur in the window layer, thereby decreasing the efficiency of photon conversion at that subcell, and thus the overall efficiency of the solar cell.

Since the window layer is directly adjacent to the emitter layer, the interface with the emitter layer is appropriately designed so as to minimize the number of minority carriers encountering the interface. Another characteristic is the deep energy levels in the band gap, and here again one wishes to minimize such deep energy levels which would tend to create sites that could participate in Shockley-Read-Hall (SRH) recombination of electron-hole pairs. Since crystal defects can cause these deep energy levels, the composition and morphology of the window layer should be capable of forming an interface with the emitter layer that would minimize the crystal defects at the interface.

However, in order to improve the efficiency of a solar cell even further, the present disclosure proposes additional design features that have heretofore not been considered.

The design characteristic of the window layer which has as its goal the minimization of minority-carrier recombination at the window layer/emitter layer interface is sometimes referred to as emitter “passivation”. Although “passivation” is a term in the field of semiconductor process technology that has various meanings depending on the specific materials and electrical properties and the context in which the term is used, such as the passivation approach as described in the Applicant's U.S. patent application Ser. No. 13/921,756, which is hereby incorporated by reference. In this disclosure, “passivation” will be used to have the meaning of incorporation of a passivating material, compound or chemical element onto the surface of the window layer, as described herein, unless otherwise noted.

Prior to the present invention, the materials and fabrication steps disclosed in the prior art have not been adequate to produce a commercially viable and energy efficient solar cell using commercially established fabrication processes for producing an inverted metamorphic multijunction cell structure.

### SUMMARY OF THE INVENTION

### Objects of the Invention

It is an object of the present invention to provide increased photoconversion efficiency in a multijunction solar cell.

It is another object of the present invention to provide increased current in a multijunction solar cell by utilizing a passivation material on the surface of the window layer, adjacent to the contact layer, of the top subcell.

It is another object of the present invention to provide increased current in a multijunction solar cell by utilizing a sulfur passivation on the surface of a window layer adjacent to an emitter layer of a subcell to prevent recombination, and drive minority carriers to the emitter layer and increase the efficiency of the solar cell.

It is another object of the present disclosure to provide a method of fabricating a multijunction solar cell by application of ammonium sulphide to the top surface of the window layer of the top subcell.

Some implementations of the present disclosure may incorporate or implement fewer of the aspects and features noted in the foregoing objects.

### Features of the Invention

In another aspect the present invention provides a multijunction solar cell including a top first solar subcell having a first band gap; a middle second solar subcell disposed directly adjacent to said first subcell and having a second band gap smaller than said first band gap; a grading interlayer disposed directly adjacent to said second subcell and having a third band gap greater than second band gap, said grading interlayer being deposited using an MOCVD process; a bottom third solar subcell disposed and directly adjacent to said grading interlayer and being lattice mismatched with respect to said middle second subcell, and having a fourth band gap smaller than said second band gap; an encapsulating layer composed of silicon nitride or titanium oxide disposed on the top surface of the solar cell; and an antireflection coating layer disposed over the encapsulating layer.

In another aspect the present invention provides a method of manufacturing a solar cell by providing a first substrate; forming an upper first solar subcell having a first band gap on said first substrate; forming a second solar subcell adjacent to said first solar subcell and having a second band gap smaller than said first band gap; totaling a first graded interlayer adjacent to said second solar subcell; said first graded interlayer having a third band gap greater than said second band gap; forming a third solar subcell adjacent to said first graded interlayer, said third subcell having a fourth band gap smaller than said second band gap such that said third subcell is lattice mismatched with respect to said second subcell; forming a second graded interlayer adjacent to said third solar subcell; said second graded interlayer having a fifth band gap greater than said fourth band gap; forming a lower fourth solar subcell adjacent to said second graded interlayer, said lower subcell having a sixth band gap smaller than said fourth band gap such that said fourth subcell is lattice mismatched with respect to said third subcell; mounting a surrogate substrate on top of fourth solar subcell; removing the first substrate; passivating the exposed surface of the solar cell with a passivating material; depositing an encapsulating layer over the passivated surface; and depositing an anti-reflection coating layer over the encapsulating layer.

In some embodiments, the passivating step is performed by application of ammonium sulphide.

In some embodiments, the encapsulating layer is composed of silicon nitride or titanium oxide.

In some embodiments, the encapsulating layer is deposited by chemical vapor deposition.

In some embodiments, the encapsulating layer is deposited by plasma enhanced chemical vapor deposition.

In some embodiments, the encapsulating layer is deposited by sputtering.

In some embodiments, the encapsulating layer is deposited by atomic layer epitaxy.

In some embodiments, the encapsulating layer is an antireflection coating composed of two layers of different indices of refraction.

In some embodiments, the encapsulating layer is deposited immediately after the passivating step.

In some embodiments, the passivating step is performed by dipping the wafer in a solution of ammonium sulphide.

In some embodiments, the lower fourth subcell has a band gap in the range of 0.6 to 0.8 eV; the third subcell has a band gap in the range of 0.9 to 1.1 eV, the second subcell has a band gap in the range of 1.35 to 1.45 eV, and the first subcell has a band gap in the range of 1.8 to 2.1 eV.

In some embodiments, the first substrate is composed of gallium arsenide or germanium, and the surrogate substrate is composed of sapphire, GaAs, glass, Ge or Si.

In some embodiments, the first graded interlayer is compositionally graded to lattice match the second subcell on one side and the third subcell on the other side, and the second graded interlayer is compositionally graded to lattice match the third subcell on one side and the bottom fourth subcell on the other side.

In some embodiments, the first graded interlayer is composed of any of the As, P. N, Sb based III-V compound semiconductors subject to the constraints of having the in-plane lattice parameter greater or equal to that of the second subcell and less than or equal to that of the third subcell, and having a band gap energy greater than that of the second subcell and of the third subcell.

In some embodiments, the second graded interlayer is composed of any of the As, P. N, Sb based III-V compound semiconductors subject to the constraints of having the in-plane lattice parameter greater or equal to that of the third subcell and less than or equal to that of the bottom fourth subcell, and having a band gap energy greater than that of the third subcell and of the fourth subcell.

In some embodiments, the first and second graded interlayers are composed of (InₓGa₁₋ₓ)_{y}Al_{1-y}As with x and y selected such that the band gap of each interlayer remains constant throughout its thickness.

In some embodiments, the band gap of the first graded interlayer remains constant at 1.5 eV, and the band gap of the second graded interlayer remains constant at 1.1 eV.

In some embodiments, the first subcell is composed of and InGaP emitter layer and an InGaP base layer, the second subcell is composed of InGaP emitter layer and a GaAs base layer, the third subcell is composed of an InGaP emitter layer and an InGaAs base layer, and the bottom fourth subcell is composed of an InGaAs base layer and an InGaAs emitter layer lattice matched to the base layer.

Some implementations of the present disclosure may incorporate or implement fewer of the aspects and features noted in the foregoing summaries.

Additional aspects, advantages, and novel features of the present disclosure will become apparent to those skilled in the art from this disclosure, including the following detailed description as well as by practice of the disclosure. While the disclosure is described below with reference to preferred embodiments, it should be understood that the disclosure is not limited thereto. Those of ordinary skill in the art having access to the teachings herein will recognize additional applications, modifications and embodiments in other fields, which are within the scope of the disclosure as disclosed and claimed herein and with respect to which the disclosure could be of utility.

### BRIEF DESCRIPTION OF THE DRAWINGS

The invention will be better and more fully appreciated by reference to the following detailed description when considered in conjunction with the accompanying drawings, wherein:

FIG. 1A is a perspective view of a polyhedral representation of a semiconductor lattice structure showing the crystal planes;

FIG. 1B is a perspective view of the GaAs crystal lattice showing the position of the gallium and arsenic atoms;

FIG. 1C is a highly simplified depiction of the atomic structure of a layer of semiconductor material composed of In, Al and P atoms as a zinc blende cubic crystal structures, such as the window layer of the top subcell in the present disclosure, in which the dangling bonds of a top layer of atoms are present on the surface of the layer;

FIG. 1D is an enlarged perspective view of an off-cut GaAs substrate showing how the off-cut results in a staircase of planar steps extending over the surface of the substrate.

FIG. 1E is a graph representing the bandgap of certain binary materials and their lattice constants;

FIG. 2 is a cross-sectional view of the solar cell of the present invention after an initial stage of fabrication including the deposition of certain semiconductor layers on the growth substrate;

FIG. 3 is a cross-sectional view of the solar cell of FIG. 2 after the next sequence of process steps;

FIG. 4 is a cross-sectional view of the solar cell of FIG. 3 after the next sequence of process steps;

FIG. 5 is a cross-sectional view of the solar cell of FIG. 4 after the next sequence of process steps;

FIG. 6 is a cross-sectional view of the solar cell of FIG. 5 after the next process step;

FIG. 7 is a cross-sectional view of the solar cell of FIG. 6 after the next process step in which a surrogate substrate is attached;

FIG. 8A is a cross-sectional view of the solar cell of FIG. 7 after the next process step in which the original substrate is removed;

FIG. 8B is another cross-sectional view of the solar cell of FIG. 8A with the surrogate substrate on the bottom of the Figure;

FIG. 9 is a simplified cross-sectional view of the solar cell of FIG. 8B after the next process step;

FIG. 10 is a cross-sectional view of the solar cell of FIG. 9 after the next process step;

FIG. 11 is a cross-sectional view of the solar cell of FIG. 10 after the next process step;

FIG. 12 is a cross-sectional view of the solar cell of FIG. 11 after the next process step;

FIG. 13 is a cross-sectional view of the solar cell of FIG. 12 after the next process step;

FIG. 14A is a highly simplified depiction of the atomic structure of a layer of semiconductor material composed of In, Al and P atoms as two interpenetrating face centered cubic lattices, such structure also known as a zinc blende cubic crystal structure, such structure representing the window layer of the top subcell in the present disclosure, in which the dangling bonds of a top layer of atoms are present on the surface of the layer;

FIG. 14B is a highly simplified depiction of the atomic structure of the top subcell window layer 336 of semiconductor material composed of In, Al and P atoms as a zinc blende cubic crystal structure, following passivation according to the present disclosure, in which the formerly dangling bonds of a top layer of atoms are bonded to sulfur atoms;

FIG. 15 is a cross-sectional view of the solar cell of FIG. 14 after the next process step;

FIG. 16 is a cross-sectional view of the solar cell of FIG. 15 after the next process step;

FIG. 17A is a top plan view of a wafer in which the solar cells are fabricated;

FIG. 17B is a bottom plan view of a wafer in which the solar cells are fabricated;

FIG. 18 is a cross-sectional view of the solar cell of FIG. 16 after the next process step;

FIG. 19 is a graph of the doping profile in a base and emitter layers of a subcell in the metamorphic solar cell according to the present invention;

FIG. 20 is a graph that depicts the current and voltage characteristics of an inverted metamorphic multijunction solar cell according to the present invention;

FIG. 21 is a diagram representing the range of band gaps of various GaInAlAs materials as a function of the relative concentration of Al, In, and Ga;

FIG. 22 is a graph representing the Ga mole fraction versus the Al to In mole fraction in GaInAlAs materials that is necessary to achieve a constant 1.5 eV band gap; and

FIG. 23 is a graph representing the mole fraction versus lattice constant in GaInAlAs materials that is necessary to achieve a constant 1.5 eV band gap band gap.

### DESCRIPTION OF THE PREFERRED EMBODIMENT

Details of the present invention will now be described including exemplary aspects and embodiments thereof. Referring to the drawings and the following description, like reference numbers are used to identify like or functionally similar elements, and are intended to illustrate major features of exemplary embodiments in a highly simplified diagrammatic manner. Moreover, the drawings are not intended to depict every feature of the actual embodiment nor the relative dimensions of the depicted elements, and are not drawn to scale.

A variety of different features of multijunction solar cells and inverted metamorphic multijunction solar cells are disclosed in the related applications noted above. Some, many or all of such features may be included in the structures and processes associated with the solar cells of the present disclosure. However, more particularly, the present disclosure is directed to the fabrication of a four junction solar cell grown on a single growth substrate. More generally, however, the present disclosure may be adapted to inverted metamorphic multijunction solar cells as disclosed in the parent application and its related applications that may include three, four, five, or six subcells, with band gaps in the range of 1.8 to 2.2 eV (or higher) for the top subcell, and 1.3 to 1.8 eV, 0.9 to 1.2 eV for the middle subcells, and 0.6 to 0.8 eV, for the bottom subcell, respectively.

The present disclosure provides a process for the design and fabrication of a window layer in a multijunction solar cell that improves light capture in the associated subcell and thereby the overall efficiency of the solar cell. More specifically, the present disclosure intends to provide a relatively simple and reproducible technique that is suitable for use in a high volume production environment in which various semiconductor layers are deposited in an MOCVD reactor, and subsequent processing steps are defined and selected to minimize any physical damage to the quality of the deposited layers, thereby ensuring a relatively high yield of operable solar cells meeting specifications at the conclusion of the fabrication processes.

Prior to discussing the specific embodiments of the present disclosure, a brief discussion of some of the issues associated with the design of multijunction solar cells, and in particular inverted metamorphic solar cells, and the context of the composition or deposition of various specific layers in embodiments of the product as specified and defined by Applicant is in order.

There are a multitude of properties that should be considered in specifying and selecting the composition of inter alia, a specific semiconductor layer, the back metal layer, the adhesive or bonding material, or the composition of the supporting material for mounting a solar cell thereon. For example, some of the properties that should be considered when selecting a particular layer or material are electrical properties (e.g. conductivity), optical properties (e.g., band gap, absorbance and reflectance), structural properties (e.g., thickness, strength, flexibility, Young's modulus, etc.), chemical properties (e.g., growth rates, the “sticking coefficient” or ability of one layer to adhere to another, stability of dopants and constituent materials with respect to adjacent layers and subsequent processes, etc.), thermal properties (e.g., thermal stability under temperature changes, coefficient of thermal expansion), and manufacturability (e.g., availability of materials, process complexity, process variability and tolerances, reproducibility of results over high volume, reliability and quality control issues).

In view of the trade-offs among these properties, it is not always evident that the selection of a material based on one of its characteristic properties is always or typically “the best” or “optimum” from a commercial standpoint or for Applicant's purposes. For example, theoretical studies may suggest the use of a quaternary material with a certain band gap for a particular subcell would be the optimum choice for that subcell layer based on fundamental semiconductor physics. As an example, the teachings of academic papers and related proposals for the design of very high efficiency (over 40%) solar cells may therefore suggest that a solar cell designer specify the use of a quaternary material (e.g., InGaAsP) for the active layer of a subcell. A few such devices may actually be fabricated by other researchers, efficiency measurements made, and the results published as an example of the ability of such researchers to advance the progress of science by increasing the demonstrated efficiency of a compound semiconductor multijunction solar cell. Although such experiments and publications are of “academic” interest, from the practical perspective of the Applicants in designing a compound semiconductor multijunction solar cell to be produced in high volume at reasonable cost and subject to manufacturing tolerances and variability inherent in the production processes, such an “optimum” design from an academic perspective is not necessarily the most desirable design in practice, and the teachings of such studies more likely than not point in the wrong direction and lead away from the proper design direction. Stated another way, such references may actually “teach away” from Applicant's research efforts and the ultimate solar cell design proposed by the Applicants.

In view of the foregoing, it is further evident that the identification of one particular constituent element (e.g. indium, or aluminum) in a particular subcell, or the thickness, band gap, doping, or other characteristic of the incorporation of that material in a particular subcell, is not a “result effective variable” that one skilled in the art can simply specify and incrementally adjust to a particular level and thereby increase the efficiency of a solar cell. The efficiency of a solar cell is not a simple linear algebraic equation as a function of the amount of gallium or aluminum or other element in a particular layer. The growth of each of the epitaxial layers of a solar cell in an MOCVD reactor is a non-equilibrium thermodynamic process with dynamically changing spatial and temporal boundary conditions that is not readily or predictably modeled. The formulation and solution of the relevant simultaneous partial differential equations covering such processes are not within the ambit of those of ordinary skill in the art in the field of solar cell design.

Even when it is known that particular variables have an impact on electrical, optical, chemical, thermal or other characteristics, the nature of the impact often cannot be predicted with much accuracy, particularly when the variables interact in complex ways, leading to unexpected results and unintended consequences. Thus, significant trial and error, which may include the fabrication and evaluative testing of many prototype devices, often over a period of time of months if not years, is required to determine whether a proposed structure with layers of particular compositions, actually will operate as intended, let alone whether it can be fabricated in a reproducible high volume manner within the manufacturing tolerances and variability inherent in the production process, and necessary for the design of a commercially viable device.

Furthermore, as in the case here, where multiple variables interact in unpredictable ways, the proper choice of the combination of variables can produce new and unexpected results, and constitute an “inventive step”.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

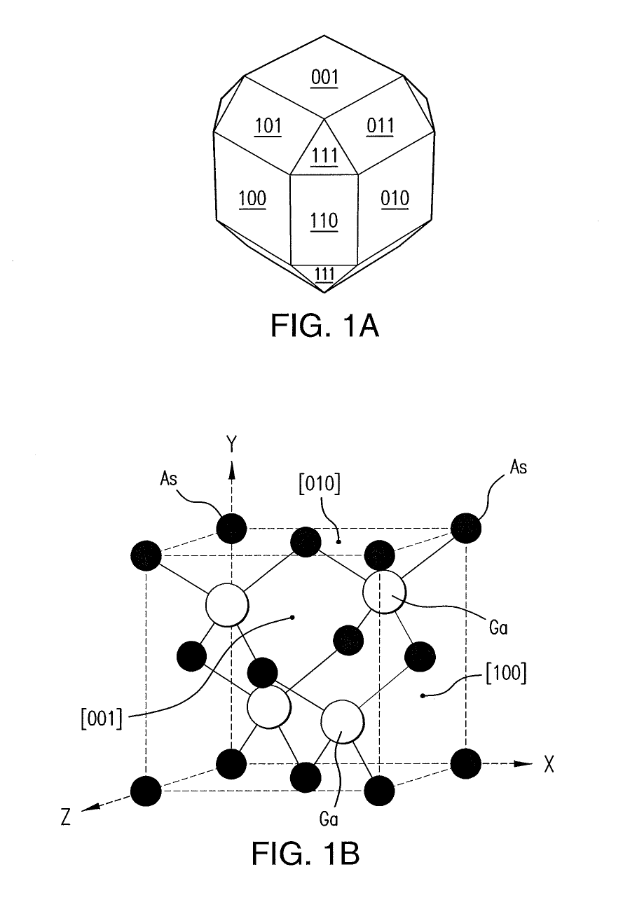

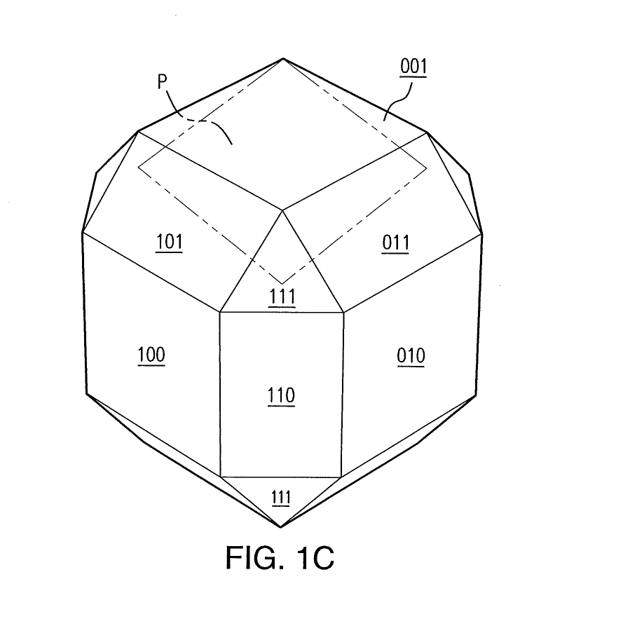

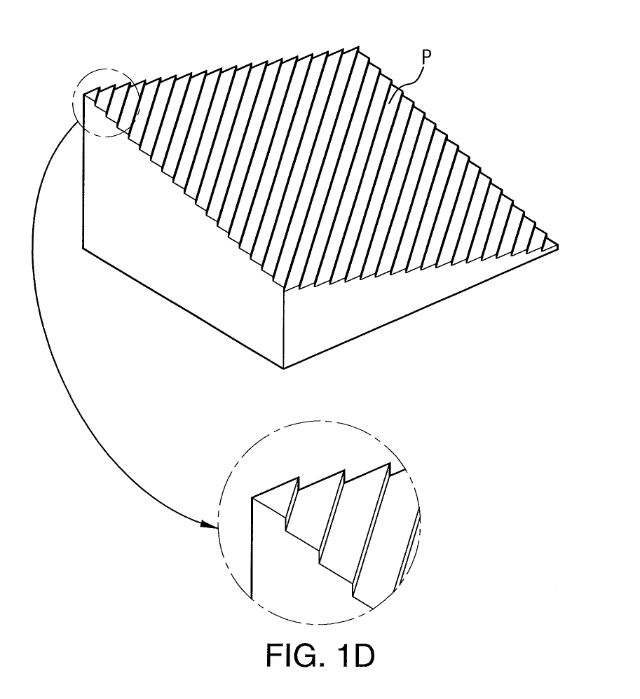

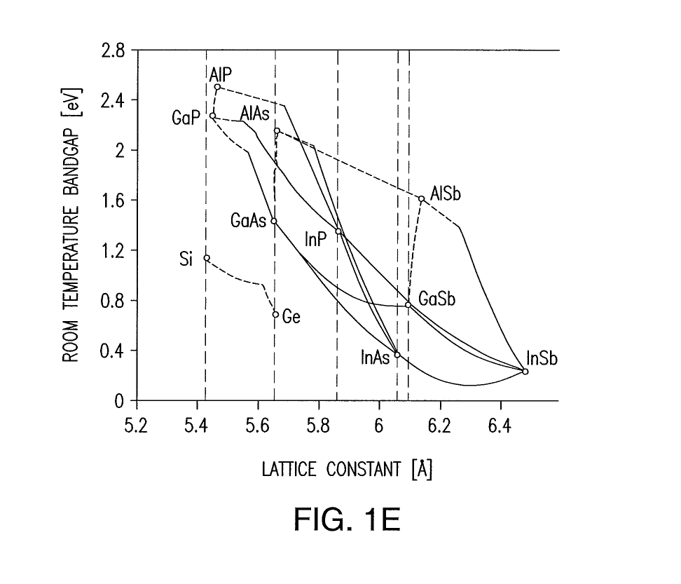

FIG. 1A is a perspective view of a polyhedral representation of a semiconductor lattice structure showing the crystal planes. The Miller indices are used to identify the planes, and the crystal structure is represented in the Figure by a truncated cube with the (001) plane at the top. In the case of a GaAs compound semiconductor, which is the material of interest in the present invention, the crystal structure is known as the zinc blende structure, and is shown in FIG. 1B, which represents a combination of two face centered cubic sublattices. The lattice constant (i.e., the distance between the arsenic atoms in the crystal) is 0.564 nm.

FIG. 1B is a perspective view of the GaAs crystal lattice showing the position of the gallium and arsenic atoms, with the corresponding Miller indices identifying the lattice planes.

FIG. 1C is a perspective view of the plane P of the substrate employed in the present invention superimposed over the crystal diagram of FIG. 1A. The plane P is seen to pivot from a point on the (001) plane (in this representation, the rear corner of the top surface of the polyhedron in the direction of the (111) plane, or more accurately the (111)A plane where the letter “A” refers to the plane formed by the sublattice or of arsenic atoms. The angle of pivot according to the present invention defines the angle of off-cut of the substrate defined from the (001) plane by the plane P, which is at least 6° and preferably approximately 15°.

FIG. 1D is an enlarged perspective view of an off-cut GaAs substrate showing how the off-cut results in a staircase of planar steps extending over the surface of the substrate.

FIG. 1E is a graph representing the band gap of certain binary materials and their lattice constants. The band gap and lattice constants of ternary materials are located on the lines drawn between typical associated binary materials (such as the ternary material AlGaAs being located between the GaAs and AlAs points on the graph, with the band gap of the ternary material lying between 1.42 eV for GaAs and 2.16 eV for AlAs depending upon the relative amount of the individual constituents). Thus, depending upon the desired band gap, the material constituents of ternary materials can be appropriately selected for growth.

The lattice constants and electrical properties of the layers in the semiconductor structure are preferably controlled by specification of appropriate reactor growth temperatures and times, and by use of appropriate chemical composition and dopants. The use of a vapor deposition method, such as Organo Metallic Vapor Phase Epitaxy (OMVPE), Metal Organic Chemical Vapor Deposition (MOCVD), or other vapor deposition methods for the growth may enable the layers in the monolithic semiconductor structure forming the cell to be grown with the required thickness, elemental composition, dopant concentration and grading and conductivity type.

The present disclosure is directed to a growth process using a metal organic chemical vapor deposition (MOCVD) process in a standard, commercially available reactor suitable for high volume production. More particularly, the present disclosure is directed to the materials and fabrication steps that are particularly suitable for producing commercially viable multijunction solar cells or inverted metamorphic multijunction solar cells using commercially available equipment and established high-volume fabrication processes, as contrasted with merely academic expositions of laboratory or experimental results.

It should be noted that the layers of a certain target composition in a semiconductor structure grown in an MOCVD process are inherently physically different than the layers of an identical target composition grown by another process, e.g. Molecular Beam Epitaxy (MBE). The material quality (i.e., morphology, stoichiometry, number and location of lattice traps, impurities, and other lattice defects) of an epitaxial layer in a semiconductor structure is different depending upon the process used to grow the layer, as well as the process parameters associated with the growth. MOCVD is inherently a chemical reaction process, while MBE is a physical deposition process. The chemicals used in the MOCVD process are present in the MOCVD reactor and interact with the wafers in the reactor, and affect the composition, doping, and other physical, optical and electrical characteristics of the material. For example, the precursor gases used in an MOCVD reactor (e.g. hydrogen) are incorporated into the resulting processed wafer material, and have certain identifiable electro-optical consequences which are more advantageous in certain specific applications of the semiconductor structure, such as in photoelectric conversion in structures designed as solar cells. Such high order effects of processing technology do result in relatively minute but actually observable differences in the material quality grown or deposited according to one process technique compared to another. Thus, devices fabricated at least in part using an MOCVD reactor or using a MOCVD process have inherent different physical material characteristics, which may have an advantageous effect over the identical target material deposited using alternative processes.

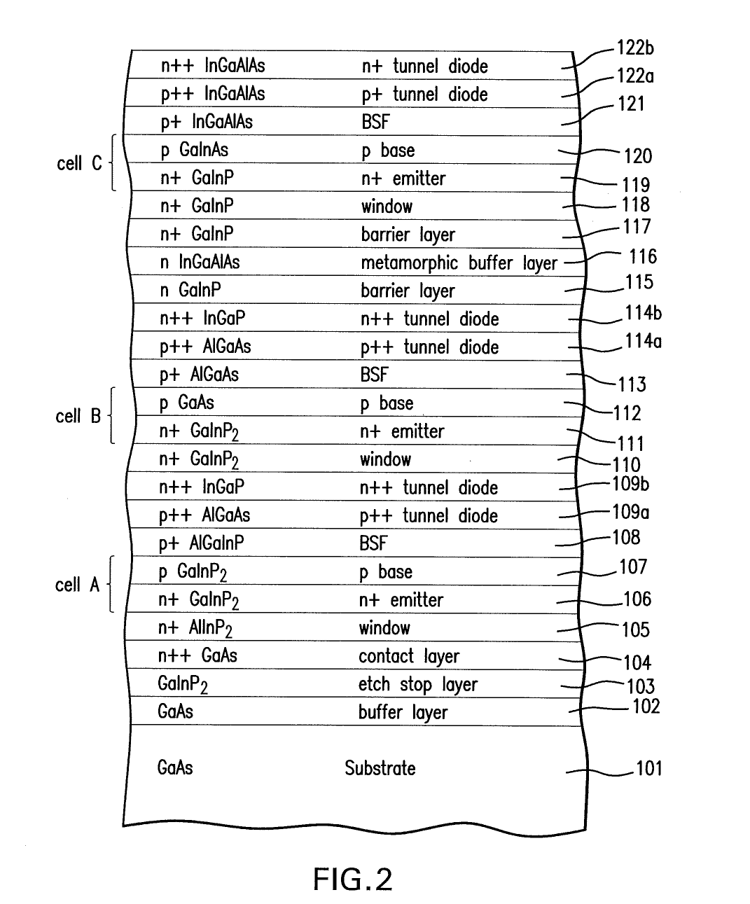

FIG. 2 depicts the multijunction solar cell according to the present invention after the sequential formation of the three subcells A, B and C on a GaAs growth substrate. More particularly, there is shown a substrate 101, which is preferably gallium arsenide (GaAs), but may also be germanium (Ge) or other suitable material. For GaAs, the substrate is preferably a 15° off-cut substrate, that is to say, its surface is orientated 15° off the (100) plane towards the (111)A plane, as more fully described in U.S. patent application Ser. No. 12/047,944, filed Mar. 13, 2008.

In the case of a Ge substrate, a nucleation layer (not shown) is deposited directly on the substrate 101. On the substrate, or over the nucleation layer (in the case of a Ge substrate), a buffer layer 102 and an etch stop layer 103 are further deposited. In the case of GaAs substrate, the buffer layer 102 is preferably GaAs. In the case of Ge substrate, the buffer layer 102 is preferably InGaAs. A contact layer 104 of GaAs is then deposited on layer 103, and a window layer 105 of AlInP is deposited on the contact layer. The subcell A, consisting of an n+ emitter layer 106 and a p-type base layer 107, is then epitaxially deposited on the window layer 105. The subcell A is generally latticed matched to the growth substrate 101.

It should be noted that the multijunction solar cell structure could be formed by any suitable combination of group III to V elements listed in the periodic table subject to lattice constant and bandgap requirements, wherein the group III includes boron (B), aluminum (Al), gallium (Ga), indium (In), and thallium (T). The group IV includes carbon (C), silicon (Si), germanium (Ge), and tin (Sn). The group V includes nitrogen (N), phosphorous (P), arsenic (As), antimony (Sb), and bismuth (Bi).

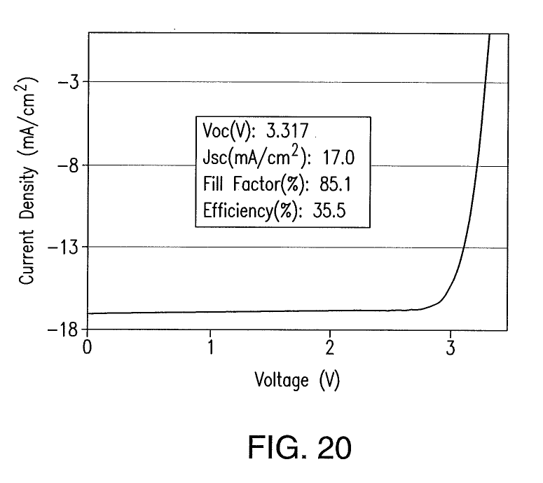

In the preferred embodiment, the emitter layer 106 is composed of InGa(Al)P and the base layer 107 is composed of InGa(Al)P. The aluminum or Al term in parenthesis in the preceding formula means that Al is an optional constituent, and in this instance may be used in an amount ranging from 0% to 30%. The doping profile of the emitter and base layers 106 and 107 according to the present invention will be discussed in conjunction with FIG. 20.

Subcell A will ultimately become the “top” subcell of the inverted metamorphic structure after completion of the process steps according to the present invention to be described hereinafter.

On top of the base layer 107 a back surface field (“BSF”) layer 108 preferably p+AlGaInP is deposited and used to reduce recombination loss.

The BSF layer 108 drives minority carriers from the region near the base/BSF interface surface to minimize the effect of recombination loss. In other words, a BSF layer 18 reduces recombination loss at the backside of the solar subcell A and thereby reduces the recombination in the base.

On top of the BSF layer 108 is deposited a sequence of heavily doped p-type and n-type layers 109a and 109b that forms a tunnel diode, i.e. an ohmic circuit element that connects subcell A to subcell B. Layer 109a is preferably composed of p++ AlGaAs, and layer 109b is preferably composed of n++ InGaP.

On top of the tunnel diode layers 109 a window layer 110 is deposited, preferably n+ InGaP. The advantage of utilizing InGaP as the material constituent of the window layer 110 is that it has an index of refraction that closely matches the adjacent emitter layer 111, as more fully described in U.S. patent application Ser. No. 12/258,190, filed Oct. 24, 2008. The window layer 110 used in the subcell B also operates to reduce the interface recombination loss. It should be apparent to one skilled in the art, that additional layer(s) may be added or deleted in the cell structure without departing from the scope of the present invention.

On top of the window layer 110 the layers of subcell B are deposited: the n-type emitter layer 111 and the p-type base layer 112. These layers are preferably composed of InGaP and In_{0.015}GaAs respectively (for a Ge substrate or growth template), or InGaP and GaAs respectively (for a GaAs substrate), although any other suitable materials consistent with lattice constant and bandgap requirements may be used as well. Thus, subcell B may be composed of a GaAs, GaInP, GaInAs, GaAsSb, or GaInAsN emitter region and a GaAs, GaInAs, GaAsSb, or GaInAsN base region. The doping profile of layers 111 and 112 according to the present invention will be discussed in conjunction with FIG. 20.

In previously disclosed implementations of an inverted metamorphic solar cell, the middle cell was a homostructure. In the present invention, similarly to the structure disclosed in U.S. patent application Ser. No. 12/023,772, the middle subcell becomes a heterostructure with an InGaP emitter and its window is converted from InAlP to InGaP. This modification eliminated the refractive index discontinuity at the window/emitter interface of the middle subcell, as more fully described in U.S. patent application Ser. No. 12/258,190, filed Oct. 24, 2008. Moreover, the window layer 110 is preferably doped three times that of the emitter 111 to move the Fermi level up closer to the conduction band and therefore create band bending at the window/emitter interface which results in constraining the minority carriers to the emitter layer.

In the preferred embodiment of the present invention, the middle subcell emitter has a band gap equal to the top subcell emitter, and the third subcell emitter has a band gap greater than the band gap of the base of the middle subcell. Therefore, after fabrication of the solar cell, and implementation and operation, neither the emitters of middle subcell B nor the third subcell C will be exposed to absorbable radiation. Substantially all of the photons representing absorbable radiation will be absorbed in the bases of cells B and C, which have narrower band gaps then the emitters. Therefore, the advantages of using heterojunction subcells are: (i) the short wavelength response for both subcells will improve, and (ii) the bulk of the radiation is more effectively absorbed and collected in the narrower band gap base. The effect will be to increase J.

On top of the cell B is deposited a BSF layer 113 which performs the same function as the BSF layer 109. The p++/n++ tunnel diode layers 114a and 114b respectively are deposited over the BSF layer 113, similar to the layers 109a and 109b, forming an ohmic circuit element to connect subcell B to subcell C. The layer 114a is preferably composed of p++ AlGaAs, and layer 114b is preferably composed of n++ InGaP.

A barrier layer 115, preferably composed of n-type InGa(Al)P, is deposited over the tunnel diode 114a/114b, to a thickness of about 1.0 micron. Such barrier layer is intended to prevent threading dislocations from propagating, either opposite to the direction of growth into the middle and top subcells B and C, or in the direction of growth into the bottom subcell A, and is more particularly described in copending U.S. patent application Ser. No. 11/860,183, filed Sep. 24, 2007.

A metamorphic layer (or graded interlayer) 116 is deposited over the barrier layer 115 using a surfactant. Layer 116 is preferably a compositionally step-graded series of InGaAlAs layers, preferably with monotonically changing lattice constant, so as to achieve a gradual transition in lattice constant in the semiconductor structure from subcell B to subcell C while minimizing threading dislocations from occurring. The band gap of layer 116 is constant throughout its thickness, preferably approximately equal to 1.5 eV, or otherwise consistent with a value slightly greater than the bandgap of the middle subcell B. The preferred embodiment of the graded interlayer may also be expressed as being composed of (InₓGa₁₋ₓ)_{y}Al_{1-y}As, with x and y selected such that the band gap of the interlayer remains constant at approximately 1.50 eV or other appropriate band gap.

In an alternative embodiment where the solar cell has only two subcells, and the “middle” cell B is the uppermost or top subcell in the final solar cell, wherein the “top” subcell B would typically have a bandgap of 1.8 to 1.9 eV, then the band gap of the interlayer would remain constant at 1.9 eV.

In the inverted metamorphic structure described in the Wanlass et al. paper cited above, the metamorphic layer consists of nine compositionally graded InGaP steps, with each step layer having a thickness of 0.25 micron. As a result, each layer of Wanlass et al. has a different bandgap. In the preferred embodiment of the present invention, the layer 116 is composed of a plurality of layers of InGaAlAs, with monotonically changing lattice constant, each layer having the same band gap, approximately 1.5 eV.

The advantage of utilizing a constant bandgap material such as InGaAlAs is that arsenide-based semiconductor material is much easier to process in standard commercial MOCVD reactors, while the small amount of aluminum assures radiation transparency of the metamorphic layers.

Although the preferred embodiment of the present invention utilizes a plurality of layers of InGaAlAs for the metamorphic layer 116 for reasons of manufacturability and radiation transparency, other embodiments of the present invention may utilize different material systems to achieve a change in lattice constant from subcell B to subcell C. Thus, the system of Wanlass using compositionally graded InGaP is a second embodiment of the present invention. Other embodiments of the present invention may utilize continuously graded, as opposed to step graded, materials. More generally, the graded interlayer may be composed of any of the As, P, N, Sb based III-V compound semiconductors subject to the constraints of having the in-plane lattice parameter greater or equal to that of the second solar cell and less than or equal to that of the third solar cell, and having a bandgap energy greater than that of the second solar cell.

In another embodiment of the present invention, an optional second barrier layer 117 may be deposited over the InGaAlAs metamorphic layer 116. The second barrier layer 117 will typically have a different composition (and band gap) than that of barrier layer 115, and performs essentially the same function of preventing threading dislocations from propagating. In the preferred embodiment, barrier layer 117 is n+ type GaInP.

A window layer 118 preferably composed of n+ type GaInP is then deposited over the barrier layer 117 (or directly over layer 116, in the absence of a second barrier layer). This window layer operates to reduce the recombination loss in subcell “C”. It should be apparent to one skilled in the art that additional layers may be added or deleted in the cell structure without departing from the scope of the present invention.

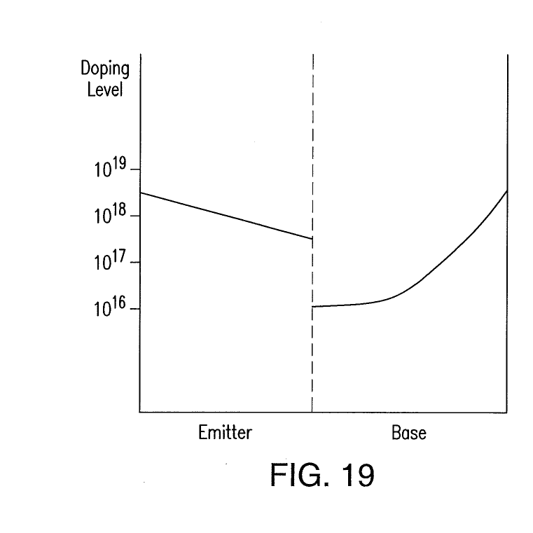

On top of the window layer 118, the layers of cell C are deposited: the n+ emitter layer 119, and the p-type base layer 120. These layers are preferably composed of n+ type InGaAs and p+ type InGaAs respectively, or n+ type InGaP and p type InGaAs for a heterojunction subcell, although another suitable material consistent with lattice constant and bandgap requirements may be used as well. The doping profile of layers 119 and 120 will be discussed in connection with FIG. 19.

A BSF layer 121, preferably composed of InGaAlAs, is then deposited on top of the cell C, the BSF layer performing the same function as the BSF layers 108 and 113.

The p++/n++ tunnel diode layers 122a and 122b respectively are deposited over the BSF layer 121, similar to the layers 114a and 114b, forming an ohmic circuit element to connect subcell C to subcell D. The layer 122a is preferably composed of p++ InGaAlAs, and layer 122b is preferably composed of n++ InGaAlAs.

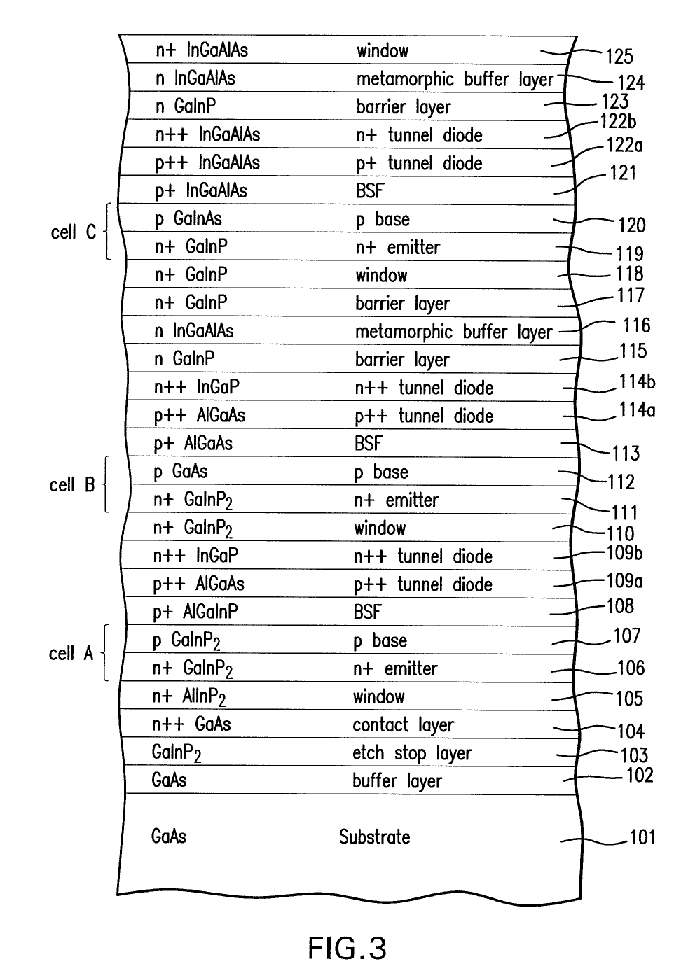

FIG. 3 depicts a cross-sectional view of the solar cell of FIG. 2 after the next sequence of process steps. A barrier layer 123, preferably composed of n-type GaInP, is deposited over the tunnel diode 122a/122b, to a thickness of about 1.0 micron. Such barrier layer is intended to prevent threading dislocations from propagating, either opposite to the direction of growth into the top and middle subcells A, B and C, or in the direction of growth into the subcell D, and is more particularly described in copending U.S. patent application Ser. No. 11/860,183, filed Sep. 24, 2007.

A metamorphic layer (or graded interlayer) 124 is deposited over the barrier layer 123 using a surfactant. Layer 124 is preferably a compositionally step-graded series of InGaAlAs layers, preferably with monotonically changing lattice constant, so as to achieve a gradual transition in lattice constant in the semiconductor structure from subcell C to subcell D while minimizing threading dislocations from occurring. The band gap of layer 124 is constant throughout its thickness, preferably approximately equal to 1.1 eV, or otherwise consistent with a value slightly greater than the band gap of the middle subcell C. The preferred embodiment of the graded interlayer may also be expressed as being composed of (InₓGa₁₋ₓ)_{y}Al_{1-y}As, with x and y selected such that the band gap of the interlayer remains constant at approximately 1.1 eV or other appropriate band gap.

A window layer 125 preferably composed of n+ type InGaAlAs is then deposited over layer 124 (or over a second barrier layer, if there is one, disposed over layer 124,). This window layer operates to reduce the recombination loss in the fourth subcell “D”. It should be apparent to one skilled in the art that additional layers may be added or deleted in the cell structure without departing from the scope of the present invention.

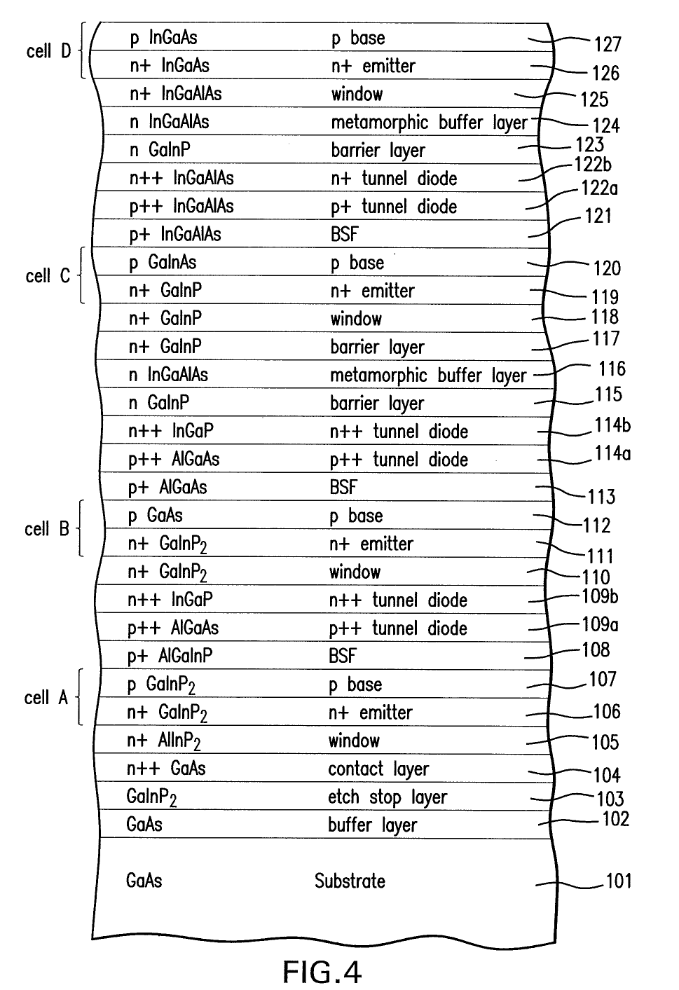

FIG. 4 depicts a cross-sectional view of the solar cell of FIG. 3 after the next sequence of process steps. On top of the window layer 125, the layers of cell D are deposited: the n+ emitter layer 126, and the p-type base layer 127. These layers are preferably composed of n+ type InGaAs and p type InGaAs respectively, or n+ type InGaP and p type InGaAs for a heterojunction subcell, although another suitable materials consistent with lattice constant and bandgap requirements may be used as well. The doping profile of layers 126 and 127 will be discussed in connection with FIG. 20.

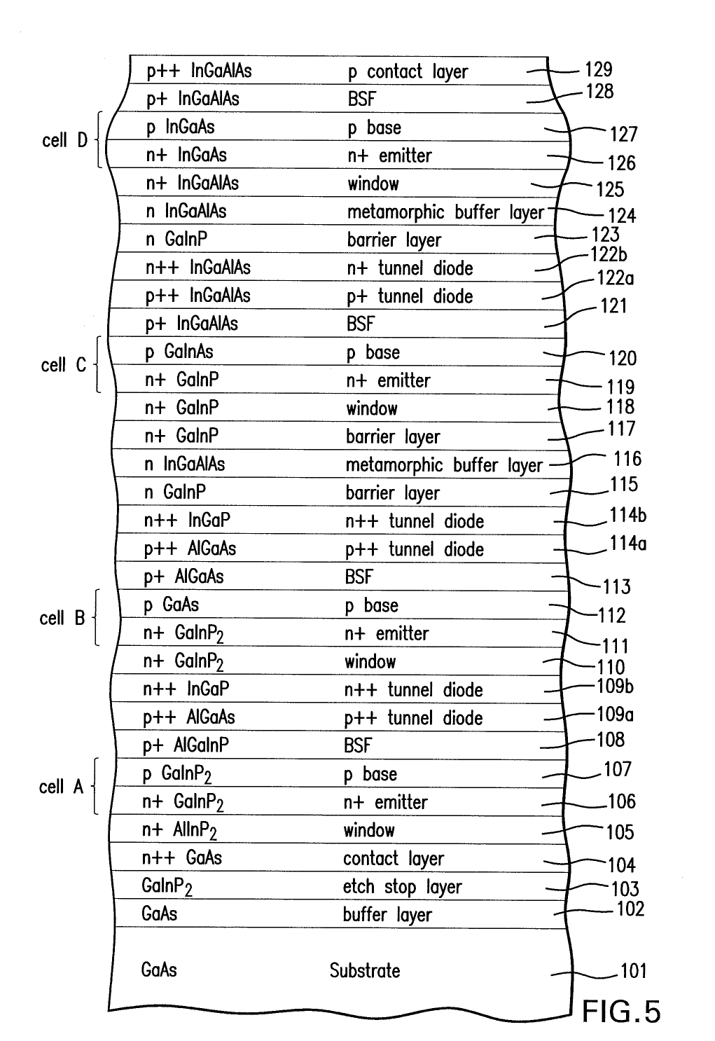

Turning next to FIG. 5, A BSF layer 128, preferably composed of p+ type InGaAlAs, is then deposited on top of the cell D, the BSF layer performing the same function as the BSF layers 108, 113 and 121.

Finally a high band gap contact layer 129, preferably composed of p++ type InGaAlAs, is deposited on the BSF layer 128.

The composition of this contact layer 129 located at the bottom (non-illuminated) side of the lowest band gap photovoltaic cell (i.e., subcell “D” in the depicted embodiment) in a multijunction photovoltaic cell, can be formulated to reduce absorption of the light that passes through the cell, so that (i) the backside ohmic metal contact layer below it (on the non-illuminated side) will also act as a mirror layer, and (ii) the contact layer doesn't have to be selectively etched off, to prevent absorption.

It should be apparent to one skilled in the art, that additional layer(s) may be added or deleted in the cell structure without departing from the scope of the present disclosure.

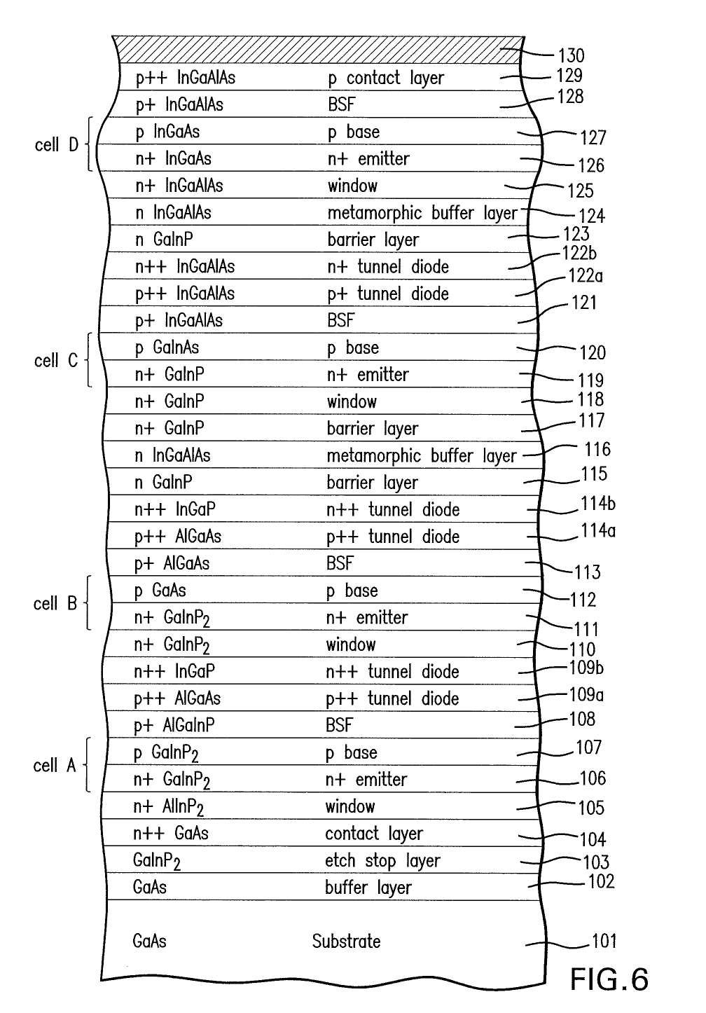

FIG. 6 is a cross-sectional view of the solar cell of FIG. 5 after the next process step in which a metal contact layer 123 is deposited over the p+ semiconductor contact layer 122. The metal is preferably the sequence of metal layers Ti/Au/Ag/Au.

Also, the metal contact scheme chosen is one that has a planar interface with the semiconductor, after heat treatment to activate the ohmic contact. This is done so that (1) a dielectric layer separating the metal from the semiconductor doesn't have to be deposited and selectively etched in the metal contact areas; and (2) the contact layer is specularly reflective over the wavelength range of interest.

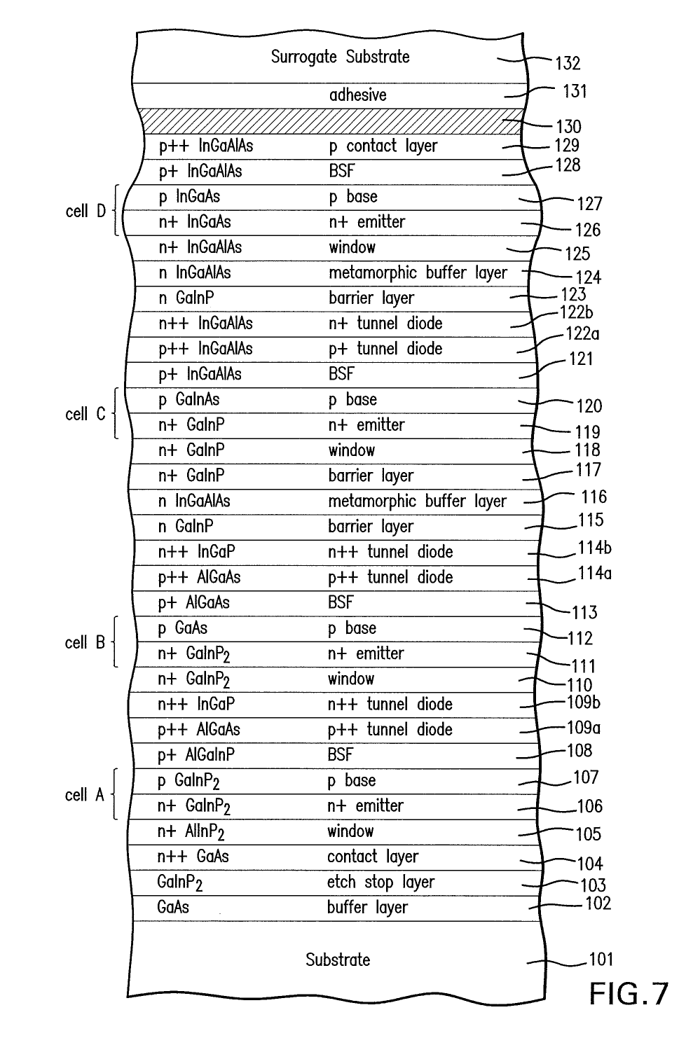

FIG. 7 is a cross-sectional view of the solar cell of FIG. 3 after the next process step in which an adhesive layer 131 is deposited over the metal layer 130. In some embodiments, the adhesive may be Wafer Bond (manufactured by Brewer Science, Inc. of Rolla, Mo.).

In the next process step, a surrogate substrate 132, in some embodiments composed of sapphire, is attached. Alternative, the surrogate substrate may be GaAs, Ge or Si, or other suitable material. The surrogate substrate is about 40 mils in thickness, and is perforated with holes about 1 mm in diameter, spaced 4 mm apart, to aid in subsequent removal of the adhesive and the substrate. As an alternative to using an adhesive layer 131, a suitable substrate (e.g., GaAs) may be eutectically or permanently bonded to the metal layer 130.

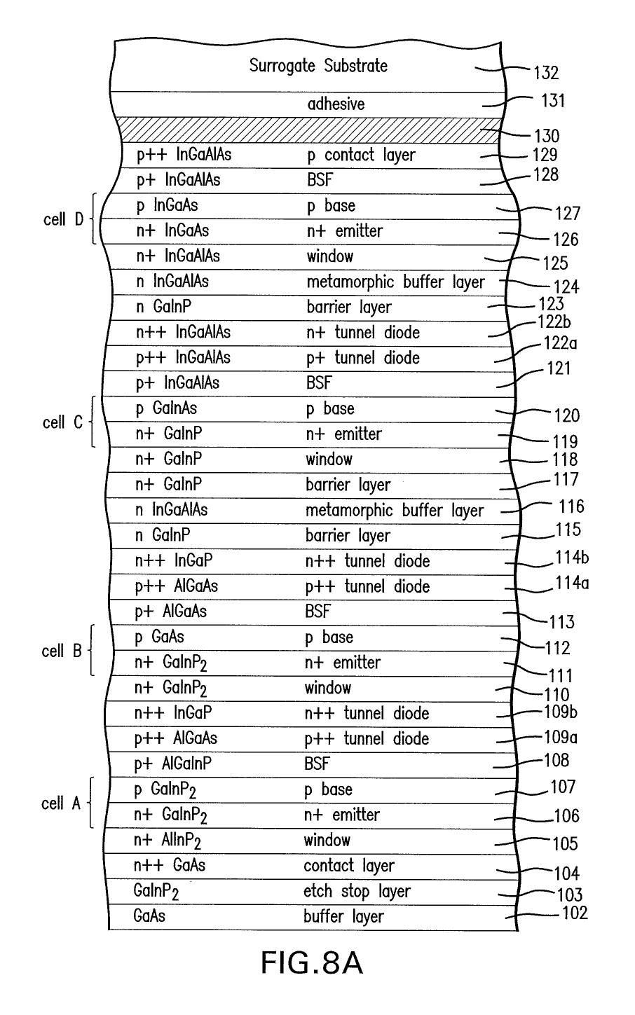

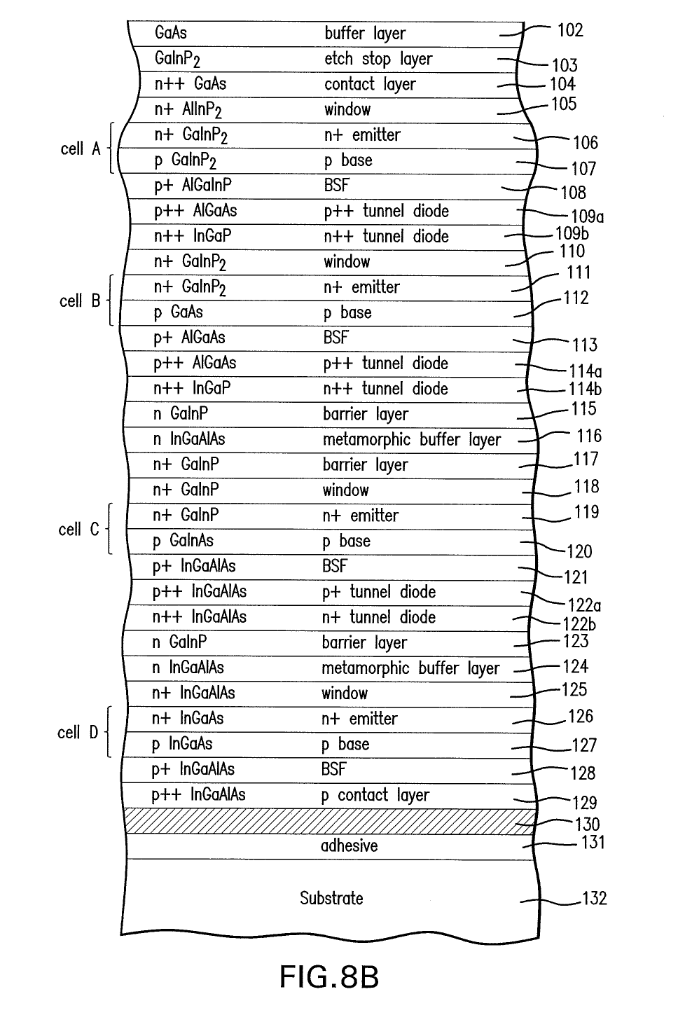

FIG. 8A is a cross-sectional view of the solar cell of FIG. 7 after the next process step in which the original substrate is removed by a sequence of lapping and/or etching steps in which the substrate 101, and the buffer layer 103 are removed. The choice of a particular etchant is growth substrate dependent.

FIG. 8B is a cross-sectional view of the solar cell of FIG. 8A with the orientation with the surrogate substrate 132 being at the bottom of the Figure. Subsequent Figures in this application will assume such orientation.

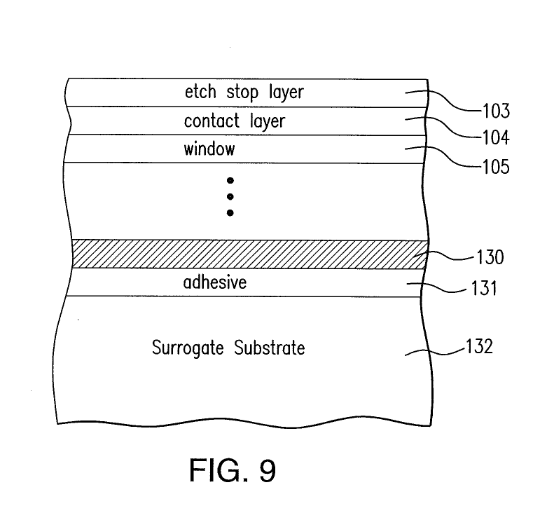

FIG. 9 is a simplified cross-sectional view of the solar cell of FIG. 8B depicting just a few of the top layers and lower layers over the surrogate substrate 132.

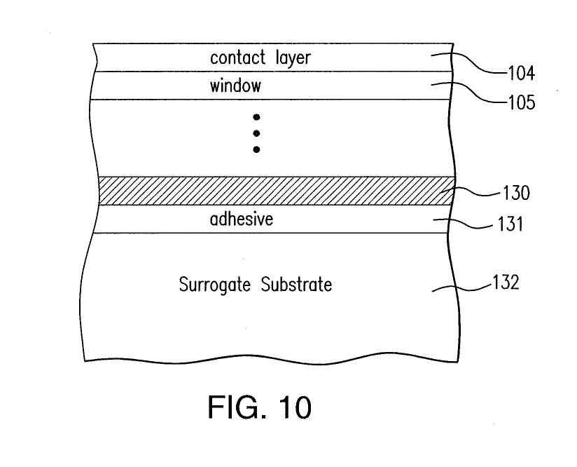

FIG. 10 is a cross-sectional view of the solar cell of FIG. 9 after the next process step in which the etch stop layer 103 is removed by a HCl/H₂O solution.

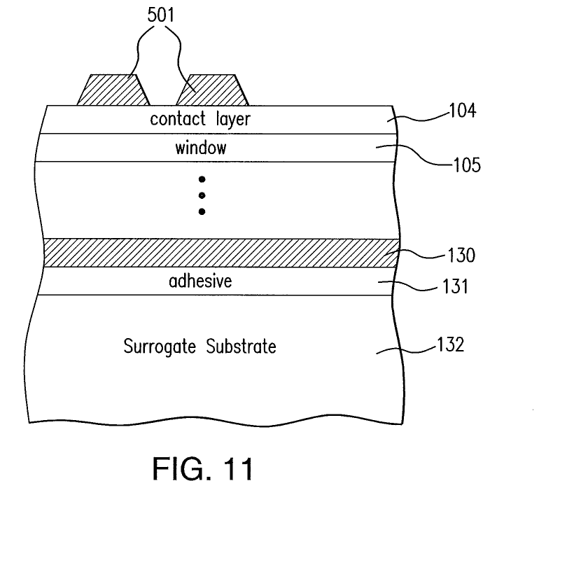

FIG. 11 is a cross-sectional view of the solar cell of FIG. 10 after the next sequence of process steps in which a photoresist mask (not shown) is placed over the contact layer 104 to form the grid lines 501. As will be described in greater detail below, the grid lines 501 are deposited via evaporation and lithographically patterned and deposited over the contact layer 104. The mask is subsequently lifted off to form the finished metal grid lines 501 as depicted in the Figures. In some embodiments, such as set forth in U.S. patent application Ser. No. 13/921,756, filed Jun. 19, 2013, herein incorporated by reference, a trench or channel 510, or portion of the semiconductor structure, is then etched around each of the solar cells down to the metal surface 517 of the metal layer 130. These channels define a peripheral boundary between the solar cell (later to be scribed from the wafer) and the rest of the wafer, and leaves a mesa structure (or a plurality of mesas, in the case of more than one solar cell per wafer) which define and constitute the solar cells later to be scribed and diced from the wafer.

As more fully described in U.S. patent application Ser. No. 12/218,582 filed Jul. 18, 2008, hereby incorporated by reference, the grid lines 501 are preferably composed of Pd/Ge/Ti/Pd/Ag/Au, although other suitable materials may be used as well.

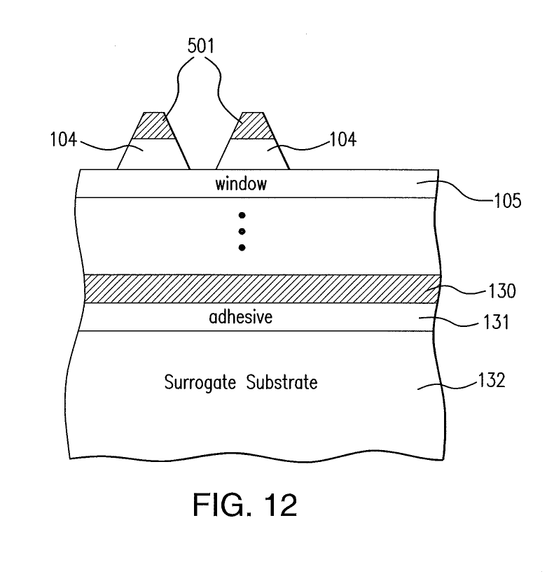

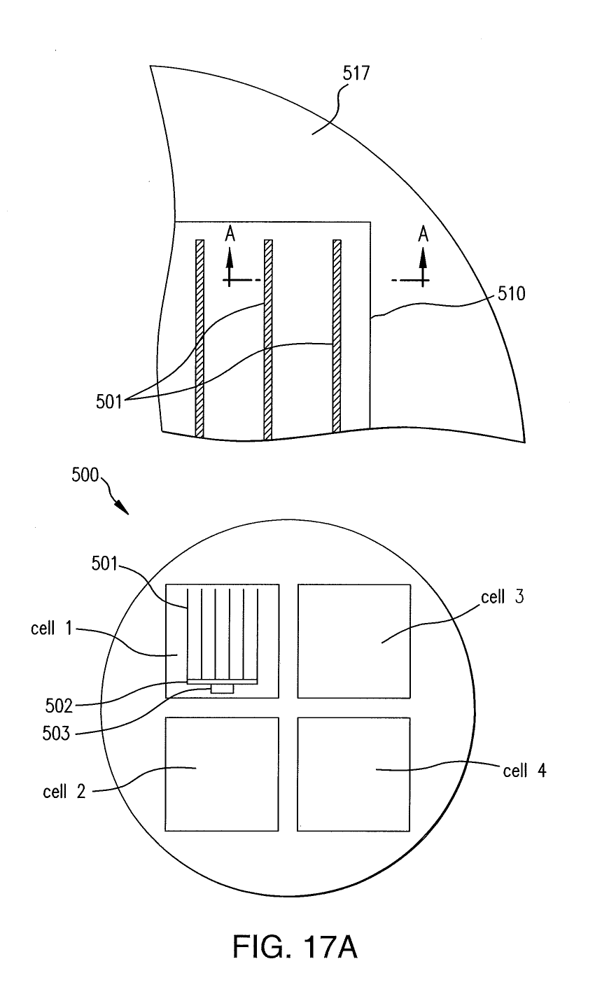

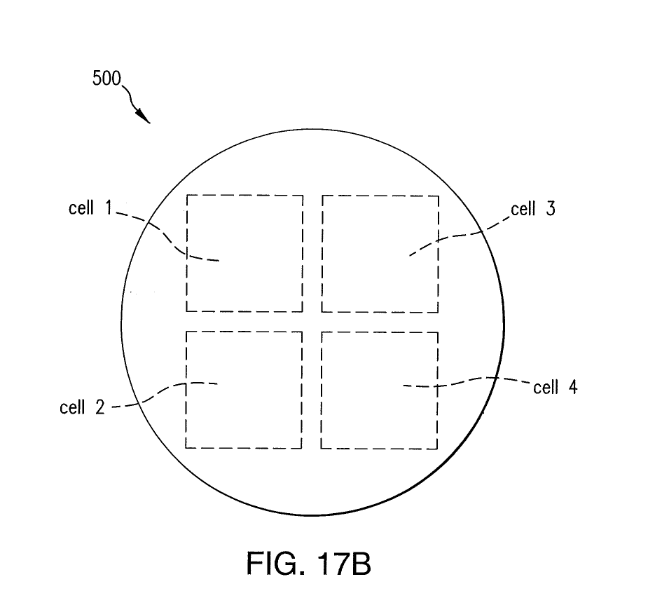

FIG. 12 is a cross-sectional view of the solar cell of FIG. 11 after the next process step in which the grid lines are used as a mask to etch down the surface to the window layer 105 using a citric acid/peroxide etching mixture. The cross-section depicted in FIG. 12 is that as seen from the A-A plane shown in FIG. 17A.

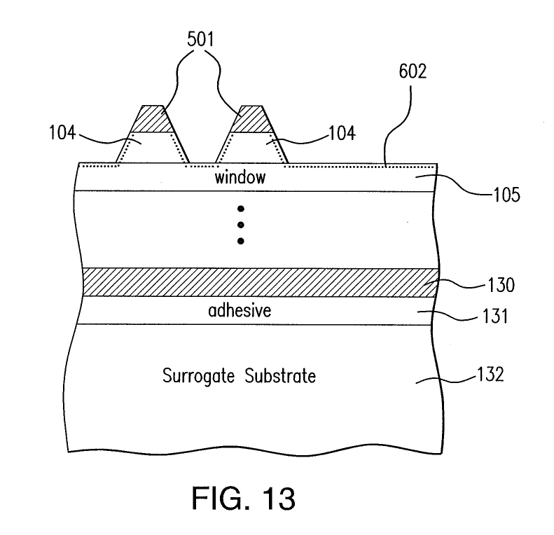

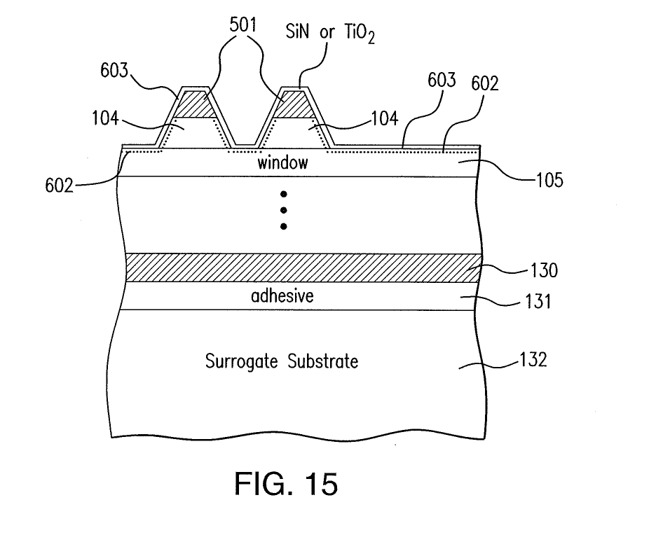

FIG. 13 is a cross-sectional view of the solar cell of FIG. 12 after the next process step of surface passivation in which the entire wafer is dipped in a solution of ammonium sulphide for a period of time at least 15 minutes. In other embodiments, the period of time may be longer depending upon the concentration of the solution. In other embodiments, the passivation of the surface may be performed by exposure to a hydrogen sulfide gas. The passivized surface is represented in the FIG. 15 by dots 602 penetrating onto the exposed surface of the window layer 105 and the exposed edge layers of the contact layer 105r.

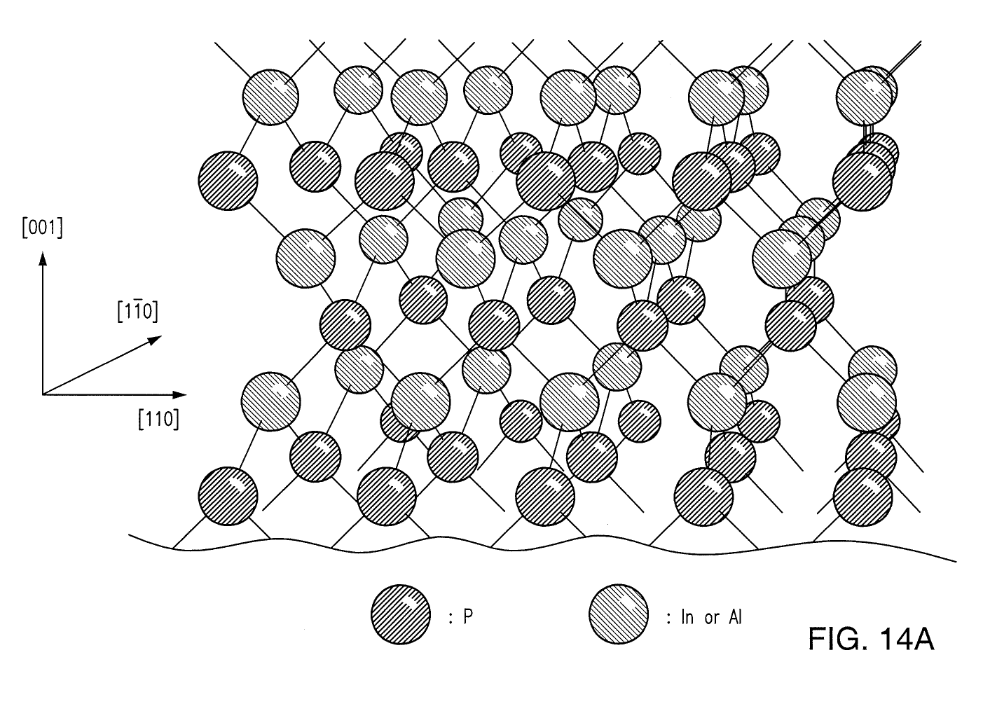

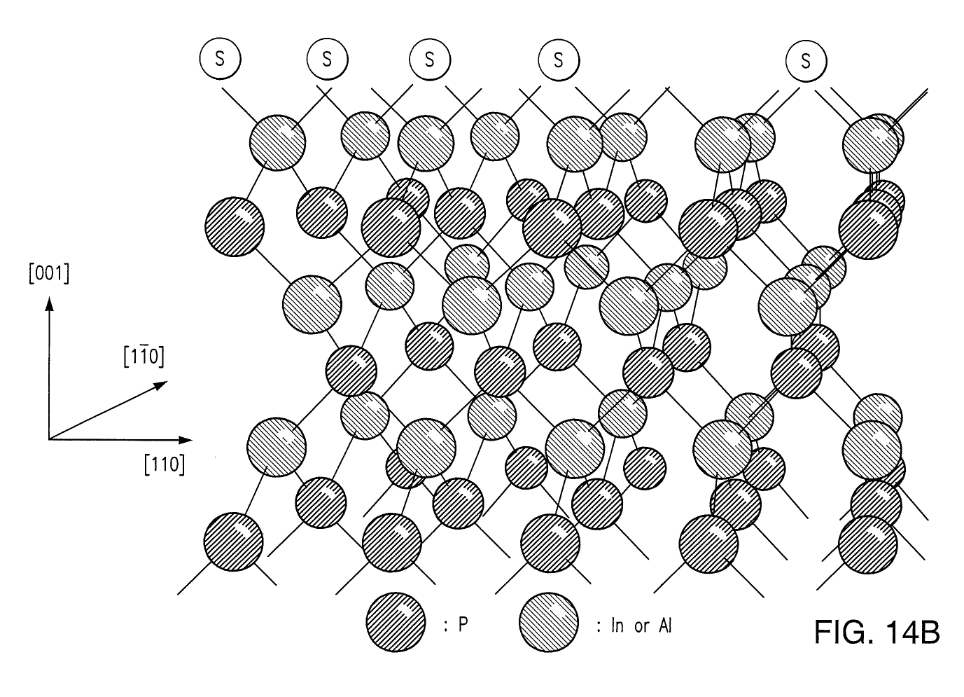

FIG. 14A is a highly simplified depiction of the atomic structure of a layer of semiconductor material composed of In, Al and P atoms as two interpenetrating face centered cubic lattices, such structure also known as a zinc blende cubic crystal structure, such structure representing the window layer of the top subcell in the present disclosure, in which the dangling bonds of a top layer of atoms are present on the surface of the layer.

FIG. 14B is a highly simplified depiction of the atomic structure of a layer of semiconductor material composed of In, Al and P atoms as a zinc blende cubic crystal structure in which the dangling bonds of a top layer of atoms as represented in FIG. 14A have been passivated by the incorporation of sulfur atoms on the ends of the bonds by a passivation process as taught by the present disclosure.

FIG. 15 a cross-sectional view of the solar cell of FIG. 13 after the next process steps in which a layer 603 of silicon nitride or titanium dioxide, generally from 50 to 100 Angstroms in thickness, is deposited by plasma enhanced chemical vapor deposition. The deposition of the layer 603 should take place reasonably soon after the passivation step, e.g. after a period of time no longer than sixty minutes, to ensure the quality of the surface of the wafer. In other embodiments, the layer 603 may be deposited by other techniques known in the art, including sputtering and/or evaporation of silicon nitride or titanium dioxide.

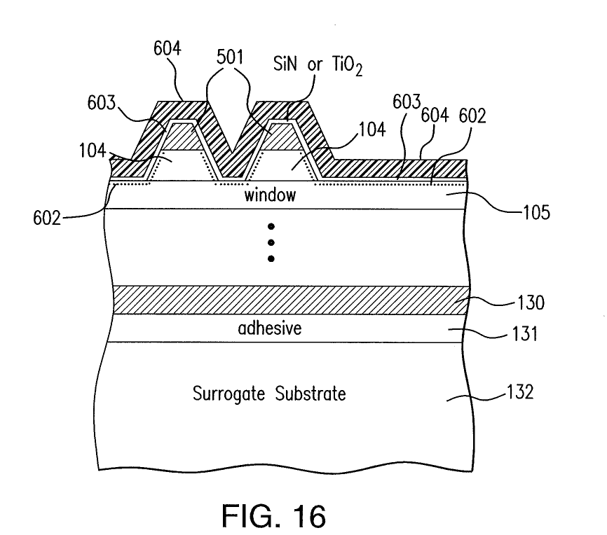

FIG. 16 a cross-sectional view of the solar cell of FIG. 15 after the next process step in which an antireflection coating (ARC) layer 604 is deposited in a thickness of 800 to 1000 Angstroms over the entire top surface of the wafer. In some embodiments, the ARC layer 604 may be deposited by sputtering or atomic layer epitaxy.

FIG. 17A is a top plan view of a wafer according to the present disclosure in which four solar cells are implemented. The depiction of four cells is for illustration for purposes only, and the present disclosure is not limited to any specific number of cells per wafer.

In each cell there are grid lines 501 (more particularly shown in cross-section in FIG. 12), an interconnecting bus line 502, and a contact pad 503. The geometry and number of grid and bus lines and the contact pad are illustrative and the present disclosure is not limited to the illustrated embodiment.

FIG. 17B is a bottom plan view of the wafer with four solar cells shown in FIG. 17A.

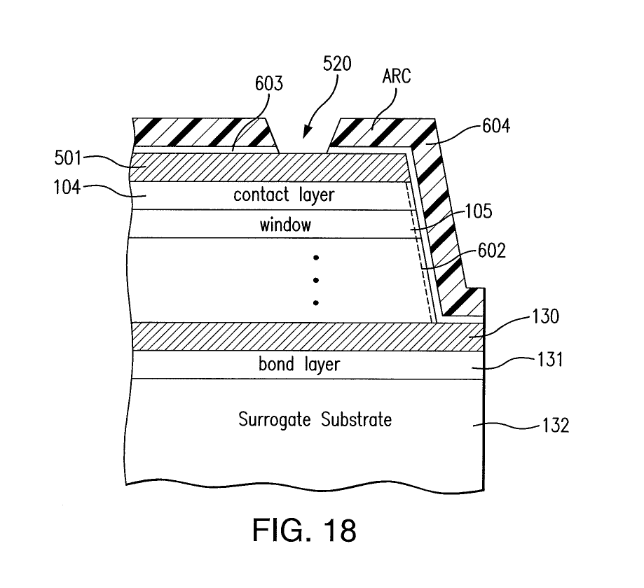

FIG. 18 is a cross-sectional view of the solar cell of FIG. 16 after the next process step in some embodiments in which a contact opening is made through the ARC layer 604 and the layer 603 of silicon nitride or titanium dioxide to a contact pad 520 on the surface of metal layer or grid line 501. The opening is made by an etching process.

FIG. 19 is a graph of a doping profile in the emitter and base layers in one or more subcells of the inverted metamorphic multijunction solar cell of the present invention. The various doping profiles within the scope of the present invention and the advantages of such doping profiles are more particularly described in copending U.S. patent application Ser. No. 11/956,069 filed Dec. 13, 2007, herein incorporated by reference. The doping profiles depicted herein are merely illustrative, and other more complex profiles may be utilized as would be apparent to those skilled in the art without departing from the scope of the present invention.

FIG. 20 is a graph that depicts the current and voltage characteristics of one of the test solar cells fabricated according to the present invention. In this test cell, the lower fourth subcell had a band gap in the range of approximately 0.6 to 0.8 eV, the third subcell had a band gap in the range of approximately 0.9 to 1.1 eV, the second subcell had a band gap in the range of approximately 1.35 to 1.45 eV and the upper subcell had a band gap in the range of 1.8 to 2.1 eV. The solar cell was measured to have an open circuit voltage (V_{oc}) of approximately 3.317 volts, a short circuit current of approximately 17.0 mA/cm², a fill factor of approximately 85.1%, and an AM0 efficiency of 35.5%.

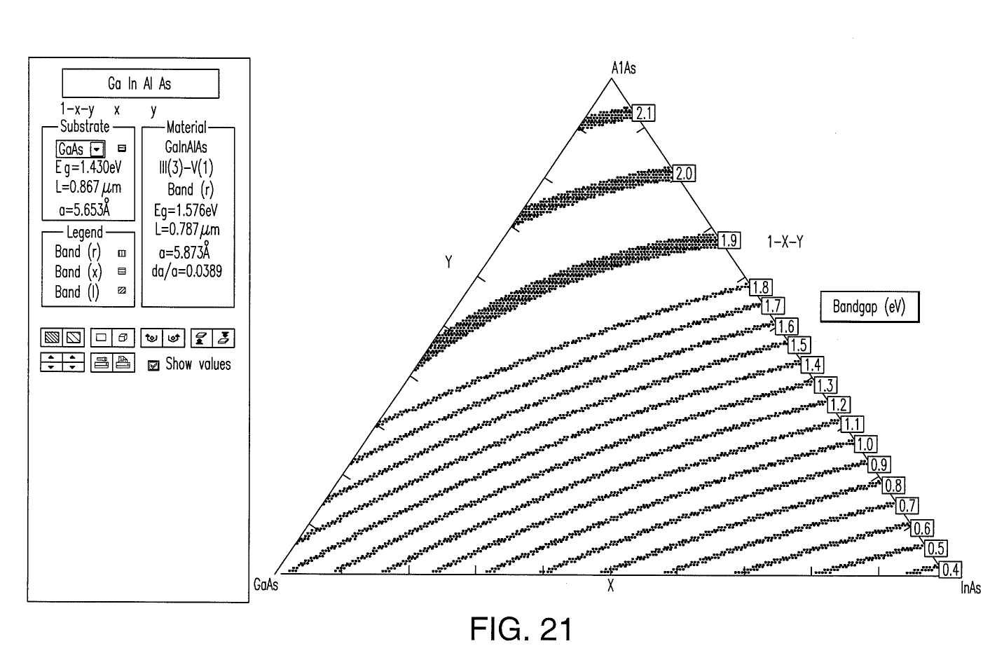

FIG. 21 is a diagram representing the range of band gaps of various GaInAlAs materials as a function of the relative concentration of Al, In, and Ga. This diagram illustrates how the selection of a constant band gap sequence of layers of GaInAlAs used in the metamorphic layer may be designed through the appropriate selection of the relative concentration of Al, In, and Ga to meet the different lattice constant requirements for each successive layer. Thus, whether 1.5 eV or 1.1 eV or other band gap value is the desired constant band gap, the diagram illustrates a continuous curve for each band gap, representing the incremental changes in constituent proportions as the lattice constant changes, in order for the layer to have the required band gap and lattice constant.

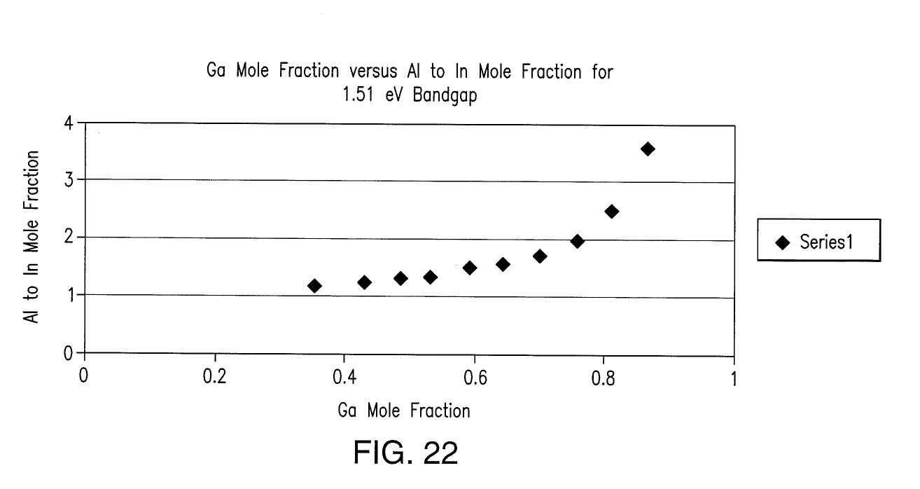

FIG. 22 is a graph that further illustrates the selection of a constant band gap sequence of layers of GaInAlAs used in the metamorphic layer by representing the Ga mole fraction versus the Al to In mole fraction in GaInAlAs materials that is necessary to achieve a constant 1.5 eV band gap.

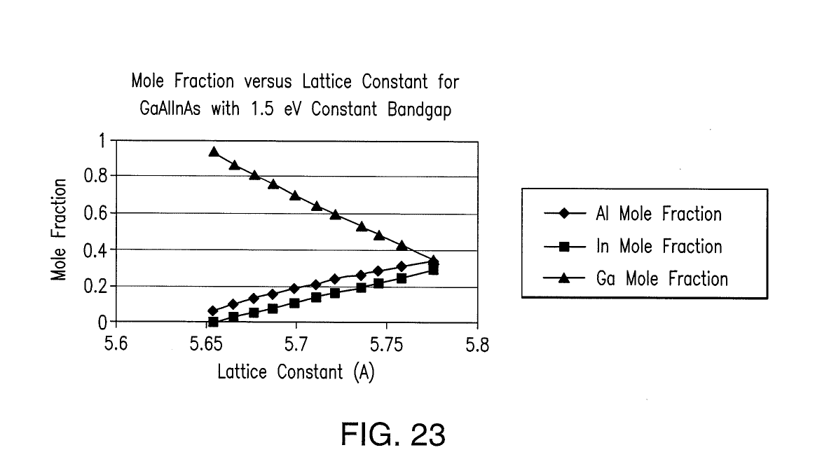

FIG. 23 is a graph that further illustrates the selection of a constant band gap sequence of layers of GaInAlAs used in the metamorphic layer by representing the mole fraction versus lattice constant in GaInAlAs materials that is necessary to achieve a constant 1.5 eV band gap band gap.

It will be understood that each of the elements described above, or two or more together, also may find a useful application in other types of structures or constructions differing from the types of structures or constructions described above.

Although described embodiments of the present disclosure utilizes a vertical stack of four subcells, various aspects and features of the present disclosure can apply to stacks with fewer or greater number of subcells, i.e. two junction cells, three junction cells, five, six, seven junction cells, etc. In the case of seven or more junction cells, the use of more than two metamorphic grading interlayer may also be utilized.

In addition, although the disclosed embodiments are configured with top and bottom electrical contacts, the subcells may alternatively be contacted by means of metal contacts to laterally conductive semiconductor layers between the subcells. Such arrangements may be used to form 3-terminal, 4-terminal, and in general, n-terminal devices. The subcells can be interconnected in circuits using these additional terminals such that most of the available photogenerated current density in each subcell can be used effectively, leading to high efficiency for the multijunction cell, notwithstanding that the photogenerated current densities are typically different in the various subcells.

As noted above, the solar cell described in the present disclosure may utilize an arrangement of one or more, or all, homojunction cells or subcells, i.e., a cell or subcell in which the p-n junction is formed between a p-type semiconductor and an n-type semiconductor both of which have the same chemical composition and the same band gap, differing only in the dopant species and types, and one or more heterojunction cells or subcells. Subcell A, with p-type and n-type GaInP is one example of a homojunction subcell. Alternatively, as more particularly described in U.S. patent application Ser. No. 12/023,772 filed Jan. 31, 2008, the solar cell of the present disclosure may utilize one or more, or all, heterojunction cells or subcells, i.e., a cell or subcell in which the p-n junction is formed between a p-type semiconductor and an n-type semiconductor having different chemical compositions of the semiconductor material in the n-type regions, and/or different band gap energies in the p-type regions, in addition to utilizing different dopant species and type in the p-type and n-type regions that form the p-n junction.

In some cells, a thin so-called “intrinsic layer” may be placed between the emitter layer and base layer, with the same or different composition from either the emitter or the base layer. The intrinsic layer may function to suppress minority-carrier recombination in the space-charge region. Similarly, either the base layer or the emitter layer may also be intrinsic or not-intentionally-doped (“NID”) over part or all of its thickness.

The composition of the window or BSF layers may utilize other semiconductor compounds, subject to lattice constant and band gap requirements, and may include AlInP, AlAs, AlP, AlGaInP, AlGaAsP, AlGaInAs, AlGaInPAs, GaInP, GaInAs, GaInPAs, AlGaAs, AlInAs, AlInPAs, GaAsSb, AlAsSb, GaAlAsSb, AlInSb, GaInSb, AlGaInSb, AlN, GaN, InN, GaInN, AlGaInN, GaInNAs, AlGaInNAs, ZnSSe, CdSSe, and similar materials, and still fall within the spirit of the present invention.

While the solar cell described in the present disclosure has been illustrated and described as embodied in a conventional multijunction solar cell, it is not intended to be limited to the details shown, since it is also applicable to inverted metamorphic solar cells, and various modifications and structural changes may be made without departing in any way from the spirit of the present invention.

Thus, while the description of the semiconductor device described in the present disclosure has focused primarily on solar cells or photovoltaic devices, persons skilled in the art know that other optoelectronic devices, such as thermophotovoltaic (TPV) cells, photodetectors and light-emitting diodes (LEDS), are very similar in structure, physics, and materials to photovoltaic devices with some minor variations in doping and the minority carrier lifetime. For example, photodetectors can be the same materials and structures as the photovoltaic devices described above, but perhaps more lightly-doped for sensitivity rather than power production. On the other hand LEDs can also be made with similar structures and materials, but perhaps more heavily-doped to shorten recombination time, thus radiative lifetime to produce light instead of power. Therefore, this invention also applies to photodetectors and LEDs with structures, compositions of matter, articles of manufacture, and improvements as described above for photovoltaic cells.

Without further analysis, from the foregoing others can, by applying current knowledge, readily adapt the present invention for various applications. Such adaptations should and are intended to be comprehended within the meaning and range of equivalence of the following claims.

1. A method of manufacturing a solar cell comprising:
providing a first substrate;
forming an upper first solar subcell having a first band gap on said first substrate;
forming a second solar subcell adjacent to said first solar subcell and having a second band gap smaller than said first band gap;
forming a first graded interlayer adjacent to said second solar subcell; said first graded interlayer having a third band gap greater than said second band gap;
forming a third solar subcell adjacent to said first graded interlayer, said third subcell having a fourth band gap smaller than said second band gap such that said third subcell is lattice mismatched with respect to said second subcell;
forming a second graded interlayer adjacent to said third solar subcell; said second graded interlayer having a fifth band gap greater than said fourth band gap;
forming a lower fourth solar subcell adjacent to said second graded interlayer, said lower subcell having a sixth band gap smaller than said fourth band gap such that said fourth subcell is lattice mismatched with respect to said third subcell;
mounting a surrogate substrate on top of fourth solar subcell;
removing the first substrate;
passivating the exposed surface of the solar cell with a passivating material;
depositing an encapsulating layer over the passivated surface; and
depositing an anti-reflection coating layer over the encapsulating layer.

2. The method as defined in claim 1, wherein the passivating step is performed by application of ammonium sulphide.

3. The method as defined in claim 1, wherein the encapsulating layer is composed of silicon nitride or titanium oxide.

4. The method as defined in claim 1, wherein the encapsulating layer is deposited by plasma enhanced chemical vapor deposition.

5. The method as defined in claim 4, wherein the encapsulating layer is deposited immediately after the passivating step.

6. The method as defined in claim 1, wherein the solar cell is implemented on a wafer, and the passivating step is performed by dipping the wafer in a solution of ammonium sulphide.

7. A method as defined in claim 1, wherein the lower fourth subcell has a band gap in the range of 0.6 to 0.8 eV; the third subcell has a band gap in the range of 0.9 to 1.1 eV, the second subcell has a band gap in the range of 1.35 to 1.45 eV, and the first subcell has a band gap in the range of 1.8 to 2.1 eV.

8. A method as defined in claim 1, wherein the first substrate is composed of gallium arsenide or germanium, and the surrogate substrate is composed of sapphire, GaAs, glass, Ge or Si.

9. A method as defined in claim 1, wherein the first graded interlayer is compositionally graded to lattice match the second subcell on one side and the third subcell on the other side, and the second graded interlayer is compositionally graded to lattice match the third subcell on one side and the bottom fourth subcell on the other side.

10. A method as defined in claim 1, wherein said first graded interlayer is composed of any of the As, P. N, Sb based III-V compound semiconductors subject to the constraints of having the in-plane lattice parameter greater or equal to that of the second subcell and less than or equal to that of the third subcell, and having a band gap energy greater than that of the second subcell and of the third subcell.

11. A method as defined in claim 1, wherein said second graded interlayer is composed of any of the As, P. N, Sb based III-V compound semiconductors subject to the constraints of having the in-plane lattice parameter greater or equal to that of the third subcell and less than or equal to that of the bottom fourth subcell, and having a band gap energy greater than that of the third subcell and of the fourth subcell.

12. A method as defined in claim 1, wherein the first and second graded interlayers are composed of (InₓGa₁₋ₓ)_{y}Al_{1-y}As with x and y selected such that the band gap of each interlayer remains constant throughout its thickness.

13. A method as defined in claim 1, wherein the band gap of the first graded interlayer remains constant at 1.5 eV, and the band gap of the second graded interlayer remains constant at 1.1 eV.

14. A method as defined in claim 11, wherein the first subcell is composed of an InGaP emitter layer and an InGaP base layer, the second subcell is composed of InGaP emitter layer and a GaAs base layer, the third subcell is composed of an InGaP emitter layer and an InGaAs base layer, and the bottom fourth subcell is composed of an InGaAs base layer and an InGaAs emitter layer lattice matched to the base layer.

15. A multijunction solar cell comprising:
a top first solar subcell having a first band gap;
a middle second solar subcell disposed directly adjacent to said first subcell and having a second band gap smaller than said first band gap;
a grading interlayer disposed directly adjacent to said second subcell and having a third band gap greater than second band gap, said grading interlayer being deposited using an MOCVD process;
a bottom third solar subcell disposed and directly adjacent to said grading interlayer and being lattice mismatched with respect to said middle second subcell, and having a fourth band gap smaller than said second band gap;
an encapsulating layer composed of silicon nitride or titanium oxide disposed on the top surface of the solar cell; and
an antireflection coating layer disposed over the encapsulating layer.

16. A method of forming a multijunction solar cell comprising an upper subcell, a middle subcell, and a lower subcell from a semiconductor substrate, the method comprising:
providing a substrate for the epitaxial growth of semiconductor material;
forming a window layer on the substrate using an MOCVD process;
forming an upper first solar subcell having a first band gap on the window layer using an MOCVD process;
forming a middle second solar subcell over said first solar subcell having a second band gap greater than said first band gap;
forming a lower third solar subcell over said second subcell having a third greater than said second band gap;
passivating the exposed surface of the solar cell of the window layer of the upper first solar subcell with a passivating material; and
depositing an encapsulating layer over the passivated surface of the window layer.

17. A method as defined in claim 16, wherein the passivating step is performed by application of ammonium sulphide.

18. The method as defined in claim 16, wherein the encapsulating layer is composed of silicon nitride or titanium oxide.

19. The method as defined in claim 16, wherein the encapsulating layer is deposited by plasma enhanced chemical vapor deposition.

20. The method as defined in claim 16, wherein the window layer is composed of InAlP.
